(19) United States
(12) Patent Application Publication
(10) Pub. No.: US 2012/0043543 A1
(43) Pub. Date: Feb. 23, 2012

(54) SEMICONDUCTOR DEVICE AND MANUFACTURING METHOD THEREFOR

(75) Inventors: Yuichi Saito, Osaka (JP); Masao Moriguchi, Osaka (JP)

(73) Assignee: SHARP KABUSHIKI KAISHA, Osaka (JP)

(21) Appl. No.: 13/264,503

(22) PCT Filed: Apr. 15, 2010
(86) PCT No.: PCT/JP2010/002740

§ 371 Date: Oct. 27, 2011

(30) Foreign Application Priority Data
Apr. 17, 2009 (JP) 2009-100480

(51) Int. Cl. H01L 29/786; H01L 21/336

(52) U.S. Cl. 257/57; 438/158; 257/E29.294; 257/E21.414

(57) ABSTRACT

Disclosed is a semiconductor device provided with the following: an active layer 6 formed on a substrate 1 having a channel region 6c, a first region 6a located on one side of the channel region 6c, and a second region 6b located on the other side of the channel region 6c; a contact formation layer 8 that is formed on the active layer 6 and that has a separation region 9, a first contact region 8a, and a second contact region 8b, the latter two of which are located on the first region 6a and the second region 6b of the active layer, respectively; a first electrode 10 electrically connected to the first region 6a through the first contact region 8a; a second electrode 11 electrically connected to the second region 6b through the second contact region 8b; and a gate electrode 2 provided with respect to the active layer 6 through a gate insulating layer 4. The active layer 6 and the first and second contact regions 8a and 8b are formed of a microcrystalline silicon film, and the separation region 9 is formed of an oxidized a microcrystalline silicon film.

### TECHNICAL FIELD

The present invention relates to a semiconductor device equipped with a thin film transistor and to a manufacturing method thereof.

### BACKGROUND ART

An active matrix substrate used in a liquid crystal display device and the like is equipped with a switching element, such as a thin film transistor (hereinafter “TFT”) or the like for each pixel. Traditionally, a TFT using an amorphous silicon film as an active layer (hereinafter “amorphous silicon TFT”) and a TFT using a polycrystalline silicon film as an active layer (hereinafter “polycrystalline silicon TFT”) have been widely used as such switching elements.

The mobility of electrons and holes in a polycrystalline silicon film is higher than the mobility in an amorphous silicon film. Therefore, a polycrystalline silicon TFT has a higher ON current than an amorphous silicon TFT, and can be operated faster. Thus, when an active matrix substrate is formed using a polycrystalline silicon TFT, the polycrystalline silicon TFT can be used not only as a switching element but also as a peripheral circuit, such as a driver and the like. As a result, a portion or the entirety of a peripheral circuit, such as a driver and the like, and a display unit can be integrally formed on the same substrate, which is advantageous. Additionally, a pixel capacitance of a liquid crystal display device or the like can be charged in a shorter switching time, which is also advantageous.

However, to manufacture the polycrystalline silicon TFT, in addition to a crystallization step by laser or heat to crystallize an amorphous silicon film, complicated steps, such as a thermal anneal step and the like, are required, causing a problem of increasing manufacturing costs per unit area of the substrate. Therefore, the polycrystalline silicon TFT is mainly used in medium-sized and small-sized liquid crystal display devices.

On the other hand, the amorphous silicon film is formed in a manner simpler than the polycrystalline silicon film, and is suitable to be used for a larger area. Thus, the amorphous silicon TFT is suited for use in an active matrix substrate of a device that requires a larger area. Although the amorphous silicon TFT has lower ON currents than the polycrystalline silicon TFT, it is used in most of the active matrix substrates of liquid crystal televisions.

However, when the amorphous silicon TFT is used, enhancement of its performance is limited because the mobility in the amorphous silicon film is low. There is a strong demand for liquid crystal display devices, such as a liquid crystal television and the like, to be larger, as well as to have higher definition and to consume lower power. It is difficult to sufficiently meet such a demand using the amorphous silicon TFT. Furthermore, especially in recent years, there has been a strong demand for a liquid crystal display device that has a driver monolithic substrate for a narrower frame and for lowering the cost, and that is high-performance, such as built-in touch panel function and the like. It is difficult to sufficiently meet such a demand using the amorphous silicon TFT.

Thus, there is an attempt to use a material other than the amorphous silicon and the polycrystalline silicon as a material of an active layer of a TFT in order to achieve a TFT offering higher performance while keeping down the number of manufacturing steps and manufacturing costs. Patent Document 1, Patent Document 2, and Non-Patent Document 1 propose that an active layer of a TFT be formed using a microcrystalline silicon (μc-Si) film. Such a TFT is referred to as a “microcrystalline silicon TFT.”

A microcrystalline silicon film is a silicon film having microcrystal grains therein, and the grain boundary of the microcrystal grains (crystal grain boundary) is mostly in an amorphous phase. Thus, it has a mixed state of a crystalline phase formed of microcrystal grains and an amorphous phase. The size of each microcrystal grain is smaller than the size of the crystal grain contained in the polycrystalline silicon film. Furthermore, as described later, in the microcrystalline silicon film, each microcrystal grain extends to form a column-shape in the direction normal to the substrate.

The microcrystalline silicon film can be formed only by a film formation step using a plasma CVD method or the like. A silane gas that is diluted with a hydrogen gas can be used as a source gas. When forming the polycrystalline silicon film, first, an amorphous silicon film is formed using a CVD device or the like, and then a step in which the amorphous silicon film is crystallized by laser or heat (crystallization step) is required. On the other hand, when forming the microcrystalline silicon film, a microcrystalline silicon film containing a primary crystalline phase can be formed by a CVD device or the like, and the crystallization step by laser or heat can be omitted. As described, the microcrystalline silicon film is formed in fewer steps than the number of steps required for forming the polycrystalline silicon film. Therefore, the microcrystalline silicon TFT can be manufactured at the same level of productivity, i.e., approximately the same number of steps and costs, as the amorphous silicon TFT. In addition, the microcrystalline silicon TFT can be manufactured using apparatus used for manufacturing the amorphous silicon TFT.

Because the microcrystalline silicon film contains microcrystal grains, it has a higher mobility than the amorphous silicon film. The mobility of the microcrystalline silicon TFT is 0.7-3 cm²/Vs, which is higher than the mobility of the amorphous silicon TFT. Because of this, in the microcrystalline silicon TFT, ON currents that are higher than those of an amorphous silicon TFT of the same size can be obtained. In this specification, the mobility of a TFT indicates the maximum field-effect mobility in a saturation region.

As described, a TFT having high ON currents can be manufactured at approximately the same productivity as the amorphous silicon TFT by using the microcrystalline silicon film without significantly increasing the manufacturing costs compared to the amorphous silicon TFT. Furthermore, the microcrystalline silicon film can be made larger with ease since it can be formed without performing complicated steps such as the crystallization step and the like as in the polycrystalline silicon film.

Patent Document 1 describes that ON currents that are 1.5 times higher than those of the amorphous silicon TFT can be obtained by using the microcrystalline silicon film as an active layer of a TFT. Non-Patent Document 1 describes that a TFT in which ON/OFF current ratio is 10⁶; the mobility is approximately 1 cm²/Vs; and the threshold is approximately 5V can be obtained by using a semiconductor film made of a microcrystalline silicon and an amorphous silicon. This mobility is higher than the mobility of the amorphous silicon TFT.

However, the microcrystalline silicone film contains many defect levels, and the band gap of the microcrystalline silicone film is smaller than a band gap of the amorphous silicon film. Thus, there is a problem that OFF currents are higher in the microcrystalline silicon TFT than in the amorphous silicon TFT. To address this problem, Patent Document 2 discloses that the thickness of a channel region in an active layer is limited to 100 nm or less in order to decrease OFF currents of the microcrystalline silicon TFT.

Typically, an inverted staggered type structure is used as a structure of the microcrystalline silicon TFT. A microcrystalline silicon TFT having the inverted staggered structure is manufactured using channel etching. Specifically, first, a gate electrode is formed on a substrate. Then, an active layer formed of microcrystalline silicon, a semiconductor film for forming a contact layer, and a conductive film are formed in this order. Then, portions of the semiconductor film and the conductive film that are located over the region that becomes a channel region of the active layer are etched (channel etching). This way, contact layers on a source side and a drain side are formed of the semiconductor film, and a source electrode and a drain electrode are formed of the conductive film. The inverted staggered type structure in which the source electrode and the drain electrode are separated by channel etching as described above is referred to as an “inverted staggered channel etching structure.” In this specification, the step in which the source electrode and the drain electrode are separated is abbreviated as a “source and drain electrodes separation step.”

However, according to the aforementioned method, a portion of the active layer is also etched by channel etching, and there may be a risk that a channel region having an even, prescribed thickness is not formed. Because of this, there is a possibility that uneven TFT characteristics occur between different points in the substrate plane, between lots, or between substrates.

To address this problem, Patent Document 2 proposes that, as a semiconductor film for forming a contact layer, an amorphous silicon film be formed over an active layer that is formed of a microcrystalline silicon, and that channel etching be conducted using the etching selectivity of the microcrystalline silicon and the amorphous silicon. Patent Document 2 discloses that, according to this method, an active layer having a thin and even thickness can be obtained because only the amorphous silicon film can be selectively removed by channel etching.

For amorphous silicon TFTs, the aforementioned inverted staggered channel etching structure is typically used (Patent Document 4, for example). However, besides this structure, there has been proposed an inverted staggered structure in which the source and drain electrodes separation is conducted using channel oxidization (Patent Document 3 and Non-Patent Document 2, for example). Such a structure is referred to as an “inverted staggered channel oxidization type structure.”

According to a manufacturing method disclosed in Patent Document 3, first, on an active layer made of an i-type (intrinsic type) amorphous silicon, an n⁺ type amorphous silicon film is formed. Then, only a portion of the n⁺ type amorphous silicon film located over a region that becomes a channel region is oxidized to form an oxidized region (channel oxidization). This way, a contact region on the source side and a contact region on the drain side can be formed of the portion of the n⁺ type amorphous silicon film that was not oxidized.

However, when an oxidization treatment (plasma oxidization, for example) is conducted to an amorphous silicon film, there may be a risk that only the surface of the amorphous silicon film is oxidized, and that the contact region on the source side is not electrically disconnected from the contact region on the drain side. Therefore, electrically disconnecting the source electrode from the drain electrode by channel oxidization is difficult, and the aforementioned manufacturing method is not practical.

### RELATED ART DOCUMENTS

Patent Documents
Patent Document 1: Japanese Patent Application Laid-Open Publication No. H6-196701
Patent Document 2: Japanese Patent Application Laid-Open Publication No. H5-304171
Patent Document 3: Japanese Patent Application Laid-Open Publication No. H5-165059
Patent Document 4: Japanese Patent Application Laid-Open Publication No. 2001-272698

Non-Patent Documents
Non-Patent Document 1: Zhongyang Xu et al., “A Novel Thin-film Transistors With μc-Si/a-Si Dual Active Layer Structure For AM-LCD,” IDW '96 Proceedings of The Third International Diplay Workshops, Volume 1, 1996, pages 117-120.
Non-Patent Document 2: Kazushige Takechi et al., “High Reliability in Back-channel-oxidized a-Si: H TFTs,” IDW '99, 1999, pages 163-166.

### SUMMARY OF THE INVENTION

### Problems to be Solved by the Invention

As described above, in the microcrystalline silicon TFT, the thickness of the channel region is preferably limited to 100 nm or less in order to decrease OFF currents. On the other hand, if the thickness of the channel region becomes too thin (less than 20 nm, for example), ON currents cannot be secured. Thus, the thickness of the channel region needs to be controlled accurately to be within a prescribed range.

However, according to a conventional method for manufacturing microcrystalline silicon TFTs, accurately controlling the thickness of the channel region is extremely difficult because a portion of the active layer is etched as well when channel etching is conducted.

Patent Document 2 proposes that a channel etching be conducted using the etching selectivity of the microcrystalline silicon and the amorphous silicon. According to this method, however, the material for the contact layer is limited to the amorphous silicon. Moreover, the etching rate of the amorphous silicon and the etching rate of the microcrystalline silicon are not significantly different. Because of this, in reality, selectively etching only the amorphous silicon film is difficult. Thus, during channel etching, there may be a risk that a portion of the active layer made of a microcrystalline silicon is removed, and that the thickness of the channel region is not controlled to be within a prescribed range.

As described, according to the conventional art, accurately controlling the thickness of the active layer (especially the channel region) made of the microcrystalline silicon is difficult. Thus, there is a problem that desired TFT characteristics cannot be obtained stably, and that reliability decreases.

The present invention seeks to address the aforementioned problems. The main object of the present invention is to provide a semiconductor device that is equipped with a microcrystalline silicon TFT having excellent characteristics and reliability, and to provide a manufacturing method of such a semiconductor device.

### Means for Solving the Problems

A semiconductor device of the present invention includes a substrate; an active layer formed on the substrate having a channel region, a first region located on one side of the channel region, and a second region located on the other side of the channel region; a contact formation layer formed on the active layer, having a first contact region located on the first region of the active layer, a second contact region located on the second region of the active layer, and a separation region located between the first contact region and the second contact region; a first electrode electrically connected to the first region through the first contact region; a second electrode electrically connected to the second region through the second contact region; and a gate electrode provided with respect to the active layer through a gate insulating layer, wherein the active layer and the first and second contact regions are made of microcrystalline silicon films, and wherein the separation region is made of an oxidized microcrystalline silicon film.

In a preferred embodiment, the semiconductor device of the present invention further includes an amorphous silicon layer between the channel region of the active layer and the separation region of the contact formation layer.

In a preferred embodiment, a volume fraction of a crystalline phase in the microcrystalline silicon film of the first and second contact regions is higher than a volume fraction of a crystalline phase in the microcrystalline silicon film of the active layer. Here, the average grain size of the microcrystal grains in the microcrystalline silicon film of the first and second contact regions may be larger than the average grain size of the microcrystal grains in the microcrystalline silicon film of the active layer.

In a preferred embodiment, the semiconductor device of the present invention further includes a protective layer formed between the gate insulating layer and a second electrode wire that includes the second electrode in a region of the substrate that is different from the region where the active layer is formed; and an interlayer insulating layer formed on the first electrode, the second electrode wire, and the protective layer, wherein a contact hole that runs through the interlayer insulating layer to reach the protective layer is formed in the interlayer insulating layer and the protective layer. The semiconductor device further includes a conductive film formed over the interlayer insulating layer and inside the contact hole, wherein the conductive film is electrically connected to the second electrode wire inside the contact hole, and wherein the protective layer includes a lower layer made of a microcrystalline silicon film and an upper layer that is formed over the lower layer and that includes an oxidized microcrystalline silicon film.

The thickness of the active layer may be 20 nm or more and 60 nm or less.

The thickness of the first and second contact regions may be 3 nm or more and 30 nm or less.

In a preferred embodiment, the active layer includes a plurality of microcrystal grains and grain boundaries located between adjacent microcrystal grains, wherein each microcrystal grain extends to form a column-shape in a direction parallel to a direction normal to the substrate.

A method for manufacturing a semiconductor device according to the present invention includes the steps of (A) forming a gate electrode on a substrate; (B) forming a gate insulating layer so as to cover the gate electrode; (C) forming a first microcrystalline silicon layer that becomes an active layer on the gate insulating layer; (D) forming a second microcrystalline silicon layer on the first microcrystalline silicon layer; and (E) oxidizing a portion of the second microcrystalline silicon layer located at a portion that becomes a channel region of the first microcrystalline silicon layer to form a separation region that divides a region of the second microcrystalline silicon layer that was not oxidized into two regions that are electrically disconnected, a first region of the two regions being a first contact region and a second region of the two regions being a second contact region, respectively.

In a preferred embodiment, a step of forming an amorphous silicon layer on the first microcrystalline silicon layer is further included between the step (C) and the step (D), wherein the second microcrystalline silicon layer is oxidized using the amorphous silicon layer as an oxidization stop layer in the step (E).

In a preferred embodiment, the step (D) includes a step of forming the second microcrystalline silicon layer having a higher volume fraction of a crystalline phase than the first microcrystalline silicon layer.

In a preferred embodiment, the method for manufacturing a semiconductor device of the present invention further includes the steps of (C′) forming a third microcrystalline silicon layer over the gate insulating layer in a region that is different from the region where the first microcrystalline silicon layer is formed, which is conducted at the same time as the step (C); (D′) forming a fourth microcrystalline silicon layer over the third microcrystalline silicon layer, which is conducted at the same time as the step (D); (F) forming a first electrode that is in contact with a region of the second microcrystalline silicon layer that becomes the first contact region and a second electrode wire including a second electrode that is in contact with a region of the second microcrystalline silicon layer that becomes the second contact region, which is conducted between the step (D) and the step (E), wherein the second electrode wire covers only a portion of the fourth microcrystalline silicon layer; (E′) oxidizing a portion of the fourth microcrystalline silicon layer that is not covered by the second electrode to form a layer including an oxidized silicon film, thereby forming a protective layer made of a layer including the third microcrystalline silicon layer and the oxidized silicon film, which is conducted at the same time as the step (E); (G) forming an interlayer insulating layer that covers the first electrode, the second electrode wire, and the protective layer, which is conducted after the step (E); (H) forming a contact hole that exposes a portion of the second electrode wire in the interlayer insulating layer and the protective layer; and (I) forming a conductive film on the interlayer insulating layer and inside the contact hole.

### Effects of the Invention

According to the present invention, in an inverted staggered type microcrystalline silicon TFT, the thickness of a channel region can be controlled more accurately than conventional methods. As a result, desired TFT characteristics can be achieved stably, and reliability can be improved. Additionally, according to the present invention, the aforementioned microcrystalline silicon TFT can be manufactured in a simple process.

### BRIEF DESCRIPTION OF THE DRAWINGS

FIG. 1(a) to FIG. 1(c) schematically show a thin film transistor according to Embodiment 1 of the present invention. FIG. 1(a) is a plan view. FIG. 1(b) and FIG. 1(c) are cross-sectional views taken along the line A-A′ and the line B-B′ of FIG. 1(a), respectively.

FIG. 2 shows an example of a method for manufacturing a thin film transistor according to Embodiment 1 of the present invention.

FIG. 3(a) to FIG. 3(c) are drawings for explaining a method for manufacturing a thin film transistor having an inverted staggered channel etching structure, which is a comparison example. FIG. 3(a) is a plan view. FIG. 3(b) and FIG. 3(c) are cross-sectional views taken along the line A-A′ and the line B-B′ of FIG. 3(a), respectively.

FIG. 4 is a graph showing characteristics of gate voltage-drain current (Vgd-Isd) of the comparison example μc-Si TFT and a reference example a-Si TFT.

FIG. 5(a), FIG. 5(b), FIG. 5(c), and FIG. 5(d) show graphs respectively showing a distribution of the mobility of TFT, the minimum OFF current, the S value, and the thickness Dc of a channel region of a semiconductor layer in a substrate plane.

FIG. 6(a), FIG. 6(b), and FIG. 6(c) show graphs respectively showing the relation of the thickness Dc of a channel region 36c of a TFT with the mobility of the TFT, with the minimum OFF current, and with the S value.

FIG. 7(a) to FIG. 7(c) are drawings for explaining manufacturing steps of a thin film transistor according to Embodiment 1 of the present invention. FIG. 7(a) is a plan view. FIG. 7(b) and FIG. 7(c) are cross-sectional views taken along the line A-A′ and the line B-B′ of FIG. 7(a), respectively.

FIG. 8(a) to FIG. 8(c) are drawings for explaining manufacturing steps of a thin film transistor of Embodiment 1 of the present invention. FIG. 8(a) is a plan view. FIG. 8(b) and FIG. 8(c) are cross-sectional views taken along the line A-A′ and the line B-B′ of FIG. 8(a), respectively.

FIG. 9(a) to FIG. 9(c) are drawings for explaining manufacturing steps of a thin film transistor of Embodiment 1 of the present invention. FIG. 9(a) is a plan view. FIG. 9(b) and FIG. 9(c) are cross-sectional views taken along the line A-A′ and the line B-B′ of FIG. 9(a), respectively.

FIG. 10(a) to FIG. 10(c) are drawings for explaining manufacturing steps of a thin film transistor of Embodiment 1 of the present invention. FIG. 10(a) is a plan view. FIG. 10(b) and FIG. 10(c) are cross-sectional views taken along the line A-A′ and the line B-B′ of FIG. 10(a), respectively.

FIG. 11(a) and FIG. 11(b) show top views illustrating active matrix substrates according to Embodiment 1 of the present invention, respectively.

FIG. 12 shows a top view illustrating a source dividing circuit of an active matrix substrate of Embodiment 1 of the present invention.

FIG. 13 schematically shows a cross-sectional view illustrating a liquid crystal display device that uses a semiconductor device according to Embodiment 1 of the present invention.

FIG. 14(a) to FIG. 14(c) schematically show another thin film transistor according to Embodiment 1 of the present invention. FIG. 14(a) is a plan view. FIG. 14(b) and FIG. 14(c) are cross-sectional views taken along the line A-A′ and the line B-B′ of FIG. 14(a), respectively.

FIG. 15(a) to FIG. 15(c) schematically show a thin film transistor according to Embodiment 2 of the present invention. FIG. 15(a) is a plan view. FIG. 15(b) and FIG. 15(c) are cross-sectional views taken along the line A-A′ and the line B-B′ of FIG. 15(a), respectively.

FIG. 16(a) to FIG. 16(c) are schematic cross-sectional views showing process steps for explaining a manufacturing method of a thin film transistor according to Embodiment 2 of the present invention.

FIG. 17(a) to FIG. 17(c) schematically show an active matrix substrate according to Embodiment 3 of the present invention. FIG. 17(a) is a plan view. FIG. 17(b) and FIG. 17(c) are cross-sectional views taken along the line E-E′ and the line F-F′ of FIG. 17(a), respectively.

FIG. 18 is a drawing for explaining an overview of a manufacturing method of an active matrix substrate according to Embodiment 3 of the present invention.

FIG. 19(a) to FIG. 19(e) are schematic cross-sectional views showing process steps for explaining a manufacturing method of an active matrix substrate of Embodiment 3.

FIG. 20(a) to FIG. 20(c) are schematic views for explaining a contact hole formation step in the manufacturing method of the active matrix substrate of Embodiment 3. FIG. 20(a) is a top view. FIG. 20(b) and FIG. 20(c) are cross-sectional views taken along the line E-E′ and the line F-F′ of FIG. 20(a), respectively.

FIG. 21(a) to FIG. 21(c) schematically show an active matrix substrate, which is a comparison example. FIG. 21(a) is a plan view. FIG. 21(b) and FIG. 21(c) are cross-sectional views taken along the line E-E′ and the line F-F′ of FIG. 21(a), respectively.

FIG. 22(a) to FIG. 22(c) are schematic views for explaining a contact hole formation step in a manufacturing method of an active matrix substrate of the comparison example. FIG. 22(a) is a top view. FIG. 22(b) and FIG. 22(c) are cross-sectional views taken along the line E-E′ and the line F-F′ of FIG. 22(a), respectively.

FIG. 23(a) to FIG. 23(c) are magnified schematic cross-sectional views illustrating an amorphous silicon film, a polycrystalline silicon film, and a microcrystalline silicon film, respectively.

FIG. 24(a) and FIG. 24(b) are a magnified schematic top view and a magnified schematic cross-sectional view illustrating a separation region 9 made of an oxidized silicon film, respectively.

### DETAILED DESCRIPTION OF EMBODIMENTS

### Embodiment 1

Embodiment 1 of a semiconductor device according the present invention is described below with reference to figures.

The semiconductor device of the present embodiment is provided with a substrate and an inverted staggered type microcrystalline silicon thin film transistor formed on the substrate. The semiconductor device of this embodiment is provided with at least one thin film transistor, and widely encompasses a substrate provided with a TFT, an active matrix substrate, a circuit including a TFT, various display devices, electronic devices, and the like.

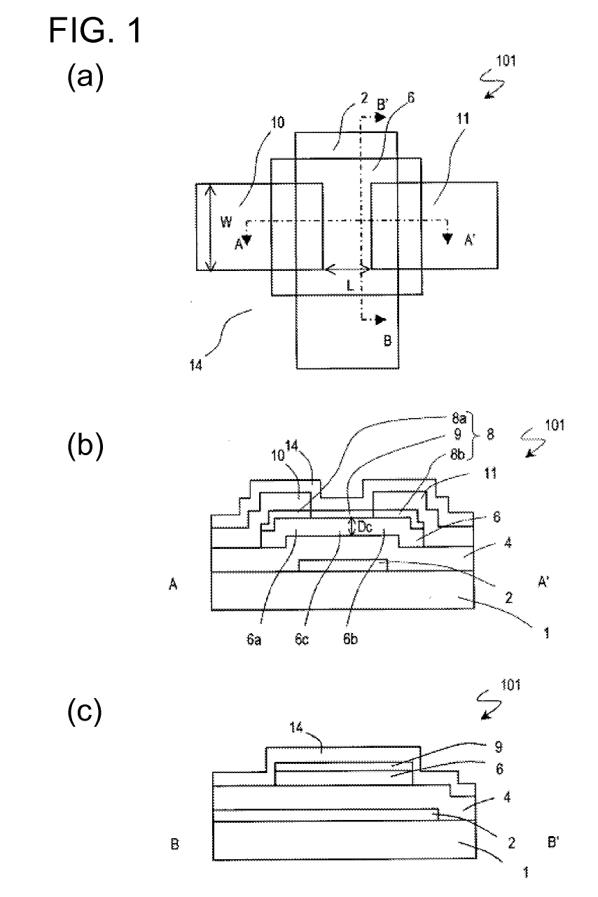

FIG. 1 schematically shows a thin film transistor 101 of the present embodiment. FIG. 1(a) is a plan view of the thin film transistor 101. FIG. 1(b) and FIG. 1(c) are cross-sectional views taken along the line A-A′ and the line B-B′ of FIG. 1(a), respectively.

The thin film transistor 101 includes a gate electrode 2 formed on a substrate 1, a gate insulating layer 4 formed to cover the gate electrode 2, a semiconductor layer (active layer) 6 formed on the gate insulating layer 4, a contact formation layer 8 formed on the semiconductor layer 6, a source electrode 10 and a drain electrode 11 respectively formed on the contact formation layer 8, and a passivation layer 14. The semiconductor layer 6 has a channel region 6c, a source region 6a located on one side of the channel region 6c, and a drain region 6b located on the other side of the channel region 6c. The contact formation layer 8 has a contact region 8a located on the source region 6a, a contact region 8b located on the drain region 6b, and a separation region 9 located between these contact regions 8a and 8b. The source electrode 10 is electrically connected to the source region 6a through the contact region 8a. The drain electrode 11 is electrically connected to the drain region 6b through the contact region 8b. In the present embodiment, a channel length L and a channel width W of the thin film transistor 101 are 3 μm and 20 μm, respectively.

The semiconductor layer 6 and the contact regions 8a and 8b of the present embodiment are made of a microcrystalline silicon film. The separation region 9 located between the contact regions 8a and 8b is made of an oxidized microcrystalline silicon film. The structure of the microcrystalline silicon film and the oxidized microcrystalline silicon film is discussed later.

As the substrate 1 of the present embodiment, an insulating substrate, such as a glass substrate, plastic substrate, or the like, can be used. Alternatively, a conductive substrate (a stainless substrate, for example) having an insulating film on its surface may be used. The substrate 1 may not be a transparent substrate. Materials for the gate electrode 2 are not particularly limited. The gate electrode 2 is formed of a TaN/Ta/TaN film, for example, which is formed by laminating TaN (tantalum nitride) and Ta (tantalum). Furthermore, materials for the gate insulating layer 4 are not limited, and may include SiNₓ (silicon nitride), for example. Although not particularly limited, the source electrode 10 and the drain electrode 11 may have a laminated structure formed of an aluminum (Al) film and a molybdenum (Mo) film, for example. Furthermore, on the source electrode 10, the drain electrode 11, and on the separation region 9, a passivation layer (interlayer insulating layer) 14 that is formed of SiNₓ (silicon nitride), for example, is provided. The passivation layer 14 may be a film of an inorganic material such as silicon nitride or the like, an organic film such as an acrylic resin or the like, or a laminated film of those.

Although not shown in the figure, in the semiconductor device of the present embodiment, in order to establish an electrical connection to the source electrode 10, the drain electrode 11, and the gate electrode 2 of the thin film transistor 101, respectively, contact holes are provided in the gate insulating layer 4 and the passivation layer 14 in other regions of the substrate 1.

Next, operation of the thin film transistor 101 is explained. In the thin film transistor 101, mobile charges are accumulated in the semiconductor layer 6 by a positive potential applied to the gate electrode 2. When the resistance of the semiconductor layer 6 becomes sufficiently small, currents (ON currents) flow from the source electrode 10 to the drain electrode 11 through the contact region 8a, the semiconductor layer 6, and the contact region 8b. On the other hand, when the resistance of the semiconductor layer 6 becomes high because of a negative potential applied to the gate electrode 2, ON currents do not flow between the source electrode 10 and the drain electrode 11. The separation region (oxidized silicon layer) 9 located between the contact region 8a and the contact region 8b has an extremely high electrical resistance, and does not function as a current path.

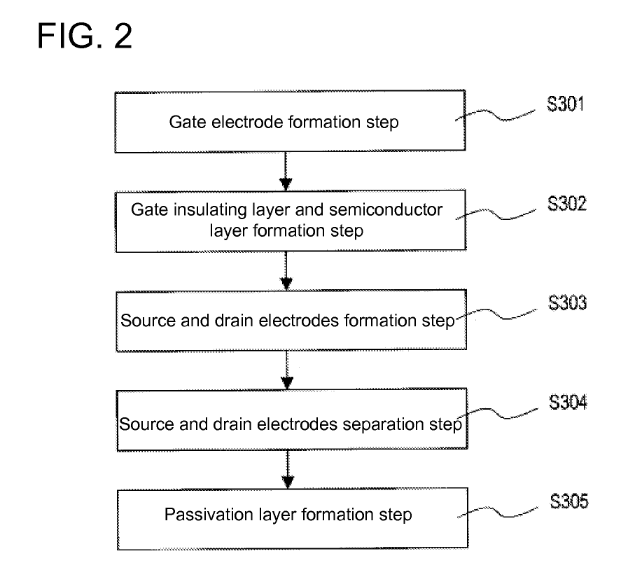

The thin film transistor 101 is manufactured by oxidizing a portion of a microcrystalline silicon film formed on the semiconductor layer 6 to separate the source and drain electrodes. An outline of a method for manufacturing the thin film transistor 101 is described below with reference to FIG. 2.

First, the gate electrode 2 is formed on the substrate 1 (step S301). Next, the gate insulating layer 4, which covers the gate electrode 2, is formed. Then, over the gate insulating layer 4, the semiconductor layer 6 made of a microcrystalline silicon and a microcrystalline silicon layer that becomes a contact formation layer are formed in this order (step S302). On the microcrystalline silicon layer, the source electrode 10 and the drain electrode 11 are formed (step S303). The source electrode 10 and the drain electrode 11 are formed so as to be located over regions of the semiconductor layer 6 that become the source region and the drain region, respectively. Thus, the surface of a portion of the microcrystalline silicon layer located over a region that becomes a channel region is exposed. Next, only the exposed portion of the microcrystalline silicon layer is oxidized to form the separation region 9 formed of an oxidized silicon layer (step S304). The portion of the microcrystalline silicon layer that was not oxidized becomes the contact regions 8a and 8b. The contact regions 8a and 8b are electrically disconnected from each other by the separation region 9. Therefore, the source electrode 10 and the drain electrode 11 can be electrically disconnected from each other by the step S304. Then, the passivation layer 14 is formed (step S305), and thus the thin film transistor 101 is obtained.

As described, in the present embodiment, the source and drain electrodes are separated by oxidizing a portion of the microcrystalline silicon film (channel oxidization) instead of performing channel etching. Therefore, damages to the surface of the channel region 6c or uneven thickness of the channel region 6c due to the source and drain electrodes separation step can be suppressed. Furthermore, the thickness of the channel region 6c can be controlled with a higher degree of accuracy. As a result, better TFT characteristics than a conventional TFT can be achieved, and reliability can be improved as well.

In the present embodiment, it is preferable to control the thickness Dc of the channel region 6c to be 20 nm or more and 60 nm or less. If the thickness Dc of the channel region 6c is 20 nm or more, mobility of the thin film transistor 101 can be high, and high ON currents can be obtained. On the other hand, if the thickness Dc of the channel region 6c is 60 nm or less, OFF currents can be reduced more effectively. Thus, OFF currents can be reduced while securing ON currents.

As described above, according to the conventional method for manufacturing a microcrystalline silicon using channel etching, a portion of the active layer is etched in the channel etching step. Because of this, accurately controlling the thickness of the channel region is extremely difficult. Patent Document 2 proposes that the channel etching step be conducted using the etching selectivity. However, even with this method, the thickness Dc of the channel region varies between TFTs, and controlling the thickness Dc of the channel region to be within the aforementioned range is extremely difficult. The reason for this is described below.

According to the method proposed in Patent Document 2, a portion of an n⁺ type amorphous silicon film formed on an active layer is etched (channel etching) to form a contact layer. On the surface of the n⁺ type amorphous silicon film, a thin oxidized silicon film, which is formed by exposure to the atmosphere, or the like, is present. Because of this, in the step of mainly etching the n⁺ type amorphous silicon film, etching of the n⁺ type amorphous silicon film is not conducted until the thin oxidized silicon film formed on the surface has been etched. The oxidized silicon film is mostly a naturally oxidized film, and its thickness has a distribution in the substrate plane. Therefore, the time before etching of the n⁺ type amorphous silicon film begins (dead time) also has a distribution in the substrate plane. As a result, the thickness Dc of the channel region obtained when the channel etching is complete has a distribution caused by the uneven thickness of the oxidized silicon film. Uneven thickness Dc of the channel region may also occur due to an etching rate distribution of a dry etching device, a thickness distribution of the n⁺ type amorphous silicon film, a thickness distribution of a microcrystalline silicon film that is the base, and the like, which should be taken into account in the conventional etching, in addition to the uneven thickness of the oxidized silicon film.

Therefore, according to the method proposed in Patent Document 2, in reality, accurately controlling the thickness Dc of the channel region to be within the range of 20 nm or more and 60 nm or less is extremely difficult. When a number of TFTs are formed over the substrate 1, the TFT characteristics decrease if the thickness Dc of the channel regions of some of the TFTs exceeds 60 nm. Thus, the product non-defect rate of the semiconductor device significantly decreases.

In contrast, in the present embodiment, the source and drain electrodes are separated by performing channel oxidization. Therefore, the thickness Dc of the channel region obtained after oxidizing the channel can be accurately controlled to be approximately the same thickness as the microcrystalline silicon film before channel oxidization (the thickness of the film when it is formed). Therefore, the thickness Dc of the channel region can be reduced (Dc=30 nm, for example), and TFT characteristics having relatively low OFF currents can be obtained. Furthermore, because the thickness Dc of the channel region can be uniform in the substrate plane, uneven TFT characteristics in the substrate plane can be reduced and reliability of the semiconductor device can be improved. In addition, because conventional channel etching is not performed, an etching distribution in the substrate plane and TFT characteristics anomalies caused by the etching distribution in the substrate plane do not occur. Thus, the product non-defect rate can be improved, and mass productivity can be increased.

In the present embodiment, a portion of the microcrystalline silicon film is oxidized (channel oxidization), and the regions that were not oxidized become the contact regions 8a and 8b. Thus, the contact regions 8a and 8b are the microcrystalline silicon film. Because such contact regions 8a and 8b have a lower electrical resistance than the contact layer (amorphous silicon layer) of the TFT of Patent Document 2, ON characteristics can be improved compared to the TFT of Patent Document 2.

Structure of Semiconductor Film 6 and Contact Formation Layer 8

The semiconductor layer 6 and the contact regions 8a and 8b of the present embodiment are preferably formed of a microcrystalline silicon film having the following characteristics.

A microcrystalline silicon film has a mixed state of a crystalline phase formed of microcrystal grains and an amorphous phase. The volume fraction of the amorphous phase to the microcrystalline silicon film can be controlled to be in a range of 5% or more and 95% or less, for example. The volume fraction of the amorphous phase is preferably 5% or more and 40% or less. This way, defects contained in the microcrystalline silicon film (defects in the film) can be reduced further. Therefore, the ON/OFF ratio of the TFT can be improved more effectively. In this specification, the volume fractions of crystalline phase, amorphous phase, and crystal grain boundaries in a film, such as the microcrystalline silicon film or the like, are represented as a ratio to the entire film.

When the microcrystalline silicon film is subjected to a Raman spectroscopy using visible light, its spectrum has the highest peak near the wavelength of 520 cm⁻¹, which is the peak of crystalline silicon, and has a broad peak near the wavelength of 480 cm⁻¹, which is the peak of amorphous silicon. The peak height of the amorphous silicon near 480 cm⁻¹ is 1/30 or more and 1 or less of the peak height of the crystalline silicon seen near 520 cm⁻¹, for example.

For comparison, when a polycrystalline silicon film is subjected to a Raman spectroscopy, little amorphous components are seen, and the peak height of the amorphous silicon is approximately 0.

Regarding the polycrystalline silicon film, depending on the crystallization conditions for forming a polycrystalline silicon film, the amorphous phase may remain at places. Even in such a case, the volume fraction of the amorphous phase to the polycrystalline silicon film is approximately less than 5%, and the peak height of the amorphous silicon according to the Raman spectroscopy is approximately less than 1/30 of the peak height of the polycrystalline silicon.

Such a microcrystalline silicon film can be formed by a CCP (capacitively coupled plasma) method, or a high-density plasma CVD, such as an ICP (inductively coupled plasma) method, for example. Depending on the system of a plasma CVD device and the film formation conditions, the aforementioned peak intensity ratio can be adjusted.

With reference to figures, the structure of a microcrystalline silicon film that is suitably used in an embodiment of the present invention is described below in comparison to the structure of a polycrystalline silicon film and an amorphous silicon film.

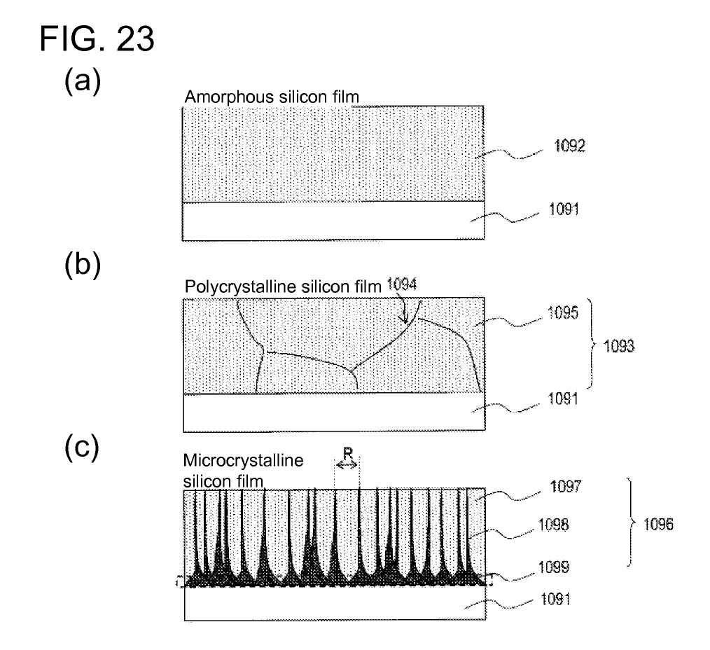

FIG. 23(a) to FIG. 23(c) are magnified schematic cross-sectional views illustrating an amorphous silicon film, a polycrystalline silicon film, and a microcrystalline silicon film, respectively.

As shown in FIG. 23(a), an amorphous silicon film 1092 is constituted of an amorphous phase on a substrate 1091. Such an amorphous silicon film 1092 is typically formed by a plasma CVD method or the like.

As shown in FIG. 23(b), a polycrystalline silicon film 1093 includes a plurality of crystal grains 1095 and crystal grain boundaries 1094 located between crystal grains. The polycrystalline silicon film 1093 is mostly constituted of crystalline silicon, and the volume fraction of the crystal grain boundaries 1094 to the polycrystalline silicon film 1093 is very low. The polycrystalline silicon film 1093 is obtained by subjecting an amorphous silicon film formed on a substrate 1091 to a crystallization step by laser or heat, for example.

As shown in FIG. 23(c), a microcrystalline silicon film 1096 includes microcrystal grains 1097 and crystal grain boundaries 1098 in the amorphous state located between adjacent microcrystal grains 1097. On the substrate 1091 side of the microcrystalline silicon film 1096, a thin amorphous layer (hereinafter referred to as an “incubation layer”) 1099 is formed. In this example, the crystal grain boundaries 1098 and the incubation layer 1099 are the amorphous phase of the microcrystalline silicon film, and the plurality of microcrystal grains 1097 are the crystalline phase.

In the example shown in FIG. 23(c), each of the microcrystal grains 1097 extends to form a column-shape from the upper surface of the incubation layer 1099 to the upper surface of the microcrystalline silicon film 1096 in the thickness-wise direction of the microcrystalline silicon film 1096. Such a microcrystalline silicon film 1096 can be formed by a plasma CVD method that is similar to the manufacturing method of the amorphous silicon film using, as a source gas, a silane gas that is diluted with a hydrogen gas, or the like, for example.

The microcrystal grain 1097 is smaller than the crystal grain 1095 (FIG. 23(b)) of the polycrystalline silicon film 1093. When a cross-section of the microcrystalline silicon film is observed using a transmission electron microscope (TEM), the average grain size of the microcrystal grain 1097 is 2 nm or more and 300 nm or less. Thus, because the cross-section of a crystal of the microcrystal grain 1097 is sufficiently smaller compared to the size of a semiconductor element, characteristics of the semiconductor element can be uniform.

In the microcrystalline silicon film 1096, the “average grain size” of the microcrystal grain 1097 indicates the average value of the width (width in a plane parallel to the substrate 1091) R of the plurality of microcrystal grains 1097.

The incubation layer 1099 tends to grow in an early stage of the microcrystalline silicon film 1096 formation. Although the thickness of the incubation layer 1099 depends on formation conditions of the microcrystalline silicon film 1096, it is 1 to 10 nm, for example. However, depending on the formation conditions, the formation method, and the material for the base of the microcrystalline silicon film 1096 such as when high-density plasma CVD is used especially, there may be a case in which the incubation layer 1099 is hardly seen.

In the microcrystalline silicon film 1096 shown in FIG. 23(c), each of the microcrystal grains 1097 is in a column-shape extending approximately in a direction normal to the substrate 1091. However, the structure of the microcrystalline silicone film in the present embodiment varies depending on the formation method and conditions of the microcrystalline silicone film, and is not limited to the structure shown in FIG. 23(c). However, regardless of the structure of the microcrystalline silicone film, the volume fraction and peak intensity ratio (ratio of the peak height of the amorphous silicon relative to the peak height of the crystalline silicon) of the amorphous phase in the microcrystalline silicon film are preferably within the aforementioned ranges. This way, a TFT having high ON characteristics can be achieved.

The semiconductor layer 6 of the present embodiment is formed of a microcrystalline silicon film of 30 nm in thickness, for example. As described with reference to FIG. 23(c), the microcrystalline silicon film has a plurality of column-shaped microcrystal grains and crystal grain boundaries constituted of the amorphous phase. For example, the volume fraction of the amorphous phase to the microcrystalline silicon film is 5 to 40%, and the peak height of the amorphous phase obtained by a Raman spectroscopy is 1/30 times or more and ⅓ times or less of the peak height of the microcrystalline portion. The average grain size of the microcrystal grains is 2 nm or more and 300 nm or less.

The contact regions 8a and 8b of the present embodiment are also formed of a microcrystalline silicon film that is similar to the semiconductor layer 6. However, it contains phosphorus (P), for example, as a dopant. Furthermore, because this microcrystalline silicon film is formed having the semiconductor layer 6, which is a microcrystalline silicon film, as a base, it grows under the influence of the base. Thus, the microcrystal grains and crystal grain boundaries extending in the direction normal to the substrate 1 inside the semiconductor layer 6 grow further in the same direction in the contact regions 8a and 8b. Because of this, the microcrystalline layer is affected by the base in the contact regions 8a and 8b, and the crystallinity (volume fraction of the crystalline phase) of the contact regions 8a and 8b becomes higher than the crystallinity of the microcrystalline silicon film of the semiconductor layer 6. As a result, the resistance of the contact regions 8a and 8b can be reduced while suppressing OFF currents. Thus, lowering of ON currents can be suppressed more effectively.

If the microcrystalline silicon films, which are to be the semiconductor layer 6 and the microcrystalline silicon film for forming the contact regions 8a and 8b, are formed under the same conditions, the average grain size of the microcrystal grains of the contact regions 8a and 8b becomes substantially the same as the average grain size of the microcrystal grains of the semiconductor layer 6, which is the base.

The separation region 9 of the present embodiment is formed of an oxidized silicon film that is made by oxidizing the microcrystalline silicon film, which is the material film of the contact regions 8a and 8b. Thus, the separation region also includes a dopant (phosphorus).

A silicon atoms inside a crystal or a crystal grain constitutes a network of mostly Si—Si bonds, and is difficult to be oxidized. However, inside a crystal grain boundary portion formed of the amorphous phase of the microcrystalline silicon film, bonds between silicon atoms tend to be defective, and more silicon atoms that are susceptible to oxidization, such as a silicon atom having a dangling bond (unbounded hand) and the like, are present than inside a crystal. Moreover, the crystal grain boundary portion is present between column-shaped microcrystals continuously in the thickness-wise direction of the microcrystalline silicon film. Because of this, when the microcrystalline silicon film is oxidized, oxidization progresses continuously from the surface of the microcrystalline silicon film towards the substrate side. As a result, the microcrystalline silicon film can be oxidized not only in the proximity of the surface but throughout its thickness-wise direction. In a manner similar to the microcrystalline silicon film before the oxidization, the oxidized silicon film obtained after the oxidization has a plurality of microcrystal grains extending to form column-shapes and a crystal grain boundary constituted of the amorphous phase. However, the crystal grain boundary of the oxidized silicon film contains oxidized silicon.

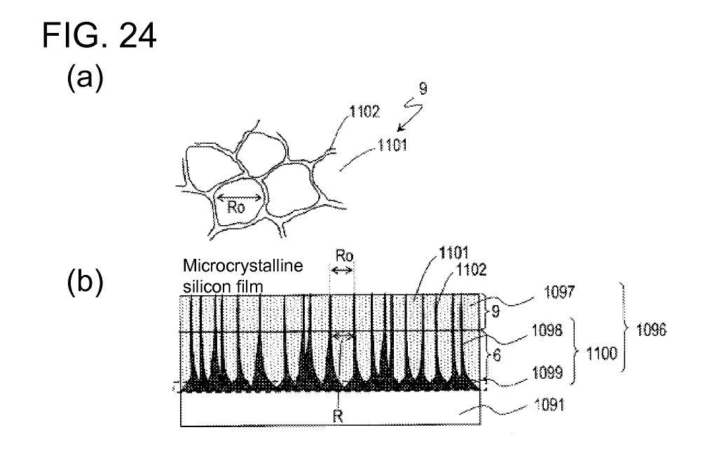

FIG. 24(a) and FIG. 24(b) are a magnified schematic top view and a magnified schematic cross-sectional view, respectively, showing the separation region 9 formed of an oxidized silicon film of the present embodiment. As shown in the figure, the separation region 9 is formed on the semiconductor layer 6, and in a manner similar to the semiconductor layer 6, includes a plurality of microcrystal grains 1101 and a crystal grain boundary 1102. In the example shown in the figure, the microcrystal grains and the crystal grain boundaries of the semiconductor layer 6 pass the interface between the semiconductor layer 6 and the separation region 9; grow further in the separation region 9; and become microcrystal grains 1101 and crystal grain boundaries 1102, respectively. Thus, the separation region 9 does not have an incubation layer. If the microcrystalline silicon film, which is to become the semiconductor layer 6, and a microcrystalline silicon film for forming the separation region 9 are formed under the same conditions, the average value of the grain size R of the microcrystal grains of the semiconductor layer 6 and the average value of the grain size Ro of the microcrystal grains of the separation region 9 are substantially equal to each other.

Patent Document 3 proposes that the source and drain electrodes be separated by anodizing a portion of an n⁺ type amorphous silicon film in an electrolytic solution. However, selectively anodizing an amorphous silicon film is not simple. When the anodization is conducted, there may be a risk that other portions of the substrate, such as, an end surface portion of a wire and the like that are not covered by a resist film or the like, for example, become damaged. On the other hand, Patent Document 3 describes that plasma oxidization may be performed instead of the anodization. However, even when plasma oxidization is performed, only the surface of the amorphous silicon film is oxidized because the amorphous silicon film has a dense film structure, and continuously oxidizing inside the film is very difficult. Thus, there is a possibility that the source electrode and the drain electrode are not electrically disconnected from each other.

In contrast, in the present embodiment, the separation region 9 for separating the source electrode 10 from the drain electrode 11 can be formed by oxidizing a microcrystalline silicon film. The microcrystalline silicon film is more susceptible to oxidization than the amorphous silicon film. For example, when the microcrystalline silicon film is merely left in the atmosphere, it becomes oxidized starting with its crystal grain boundary portion, deteriorating over time. Furthermore, in the microcrystalline silicon film, the crystal grain boundary portion extends in the thickness-wise direction of the microcrystalline silicon film, and almost no incubation layer is formed because of the effects from the base. When such a microcrystalline silicon film is subjected to an oxidization treatment such as the plasma oxidization or the like, the microcrystalline silicon film can be oxidized with ease throughout its thickness-wise direction because oxidization progresses along the crystal grain boundary. As a result, the source electrode and the drain electrode can be separated from each other more securely. Thus, according to the present embodiment, a semiconductor device equipped with a microcrystalline silicon TFT can be manufactured by a method that is convenient and suitable for mass production.

The microcrystalline silicon film of the contact regions 8a and 8b of the present embodiment is affected by the semiconductor layer 6, which is the base, and has a higher crystallinity than the microcrystalline silicon film of the semiconductor layer 6. It is preferable to further increase the crystallinity of the microcrystalline silicon film of the contact regions 8a and 8b because the resistance of the contact regions 8a and 8b can be reduced more effectively. Here, “the microcrystalline silicon film has a high crystallinity” means a state in which the volume fraction of the amorphous phase to the microcrystalline silicon film is low and the volume fraction of the crystalline phase constituted of microcrystal grains is high. When the crystallinity increases, the peak height of the amorphous phase obtained by a Raman spectroscopy becomes relatively low compared to the peak height of the crystalline phase. Further, by increasing the average grain size of the microcrystal grains included in the microcrystalline silicon film, for example, the occupation ratio of the crystal grain boundary in the amorphous state becomes smaller. Therefore, the crystallinity of the microcrystalline silicon film can be increased. Here, the crystallization rate of the microcrystalline silicon film (volume fraction of the crystalline layer) depends on the average grain size of the microcrystal grains×density. Thus, there may be a case that the crystallinity does not increase even when the average grain size is large.

The crystallinity of the microcrystalline silicon film can be appropriately adjusted depending on film formation conditions. When the microcrystalline silicon film is formed by a plasma CVD method, for example, the crystallinity can be increased by lowering the total flow volume of a gas for film formation, and/or by lowering the high-frequency power at the time of film formation, or the like, to reduce the speed of film growth. The crystallinity of the microcrystalline silicon film (volume fraction of the crystalline phase) of the contact regions 8a and 8b of the present embodiment is 65% or more and 95% or less, for example. The volume fraction of the crystalline phase of the microcrystalline silicon film of the semiconductor layer 6 is 60% or more and 90% or less, for example.

The structure of a thin film transistor of the present embodiment is not limited to the structure shown in FIG. 1(a) to FIG. 1(c). It may not have the passivation layer 14, for example. A plurality of channel regions 6c may be formed between the source region 6a and the drain region 6b of the semiconductor layer 6.

A semiconductor device of the present embodiment preferably includes a microcrystalline silicon TFT having a bottom gate structure. Because most of the conventional amorphous silicon TFTs have the bottom gate structure, manufacturing equipments used for manufacturing conventional amorphous silicon TFTs can be used, and a process having high mass productivity can be achieved.

### Comparison Example 1

Below, a microcrystalline silicon (μc-Si) thin film transistor having an inverted staggered channel etching structure was manufactured as a comparison example 1, and its characteristics were studied. In addition, the relation between the thickness of a semiconductor layer and TFT characteristics was studied. The method and results thereof are described.

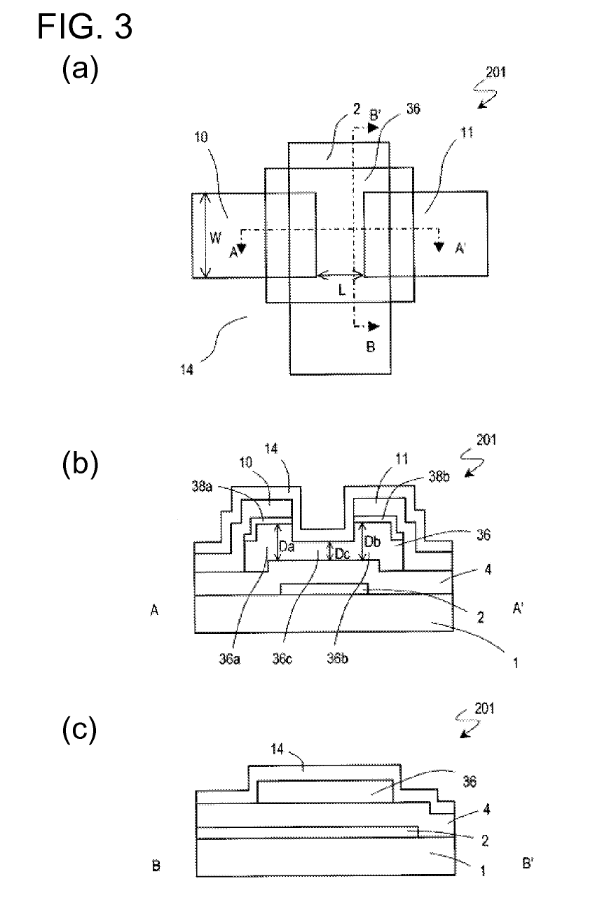

FIG. 3 schematically shows a μc-Si thin film transistor 201 having an inverted staggered channel etching structure. FIG. 3(a) is a plan view of the thin film transistor 201. FIG. 3(b) and FIG. 3(c) are cross-sectional views taken along the line A-A′ and the line B-B′ of FIG. 3(a), respectively. Below, for convenience, components similar to those in the thin film transistor 101 shown in FIG. 1 are given the same reference characters, and explanation is omitted.

The thin film transistor 201 includes a gate electrode 2 formed on a substrate 1, a gate insulating layer 4 formed to cover the gate electrode 2, a semiconductor layer 36 formed on the gate insulating layer 4, contact layers 38a and 38b formed on the semiconductor layer 36, a source electrode 10 and a drain electrode 11 formed on the contact layers 38a and 38b, respectively, and a passivation layer 14.

The semiconductor layer 36 has a channel region 36c, a source region 36a located on one side of the channel region 36c, and a drain region 36b located on the other side of the channel region 36c. The channel region 36c is located in the proximity of an opening portion (gap portion) between the source electrode 10 and the drain electrode 11. The source region 36a is electrically connected to the source electrode 10 by the contact layer 38a. The drain region 36b is electrically connected to the drain electrode 11 by the contact layer 38b.

The semiconductor layer 36 is formed of a microcrystalline silicon film. As described above with reference to FIG. 23(c), this microcrystalline silicon film has a plurality of column-shaped microcrystal grains and a crystal grain boundary, which is an amorphous phase. The contact layers 38a and 38b are formed of an n⁺ type amorphous silicon film that contains phosphorus (P) as a dopant.

The contact layers 38a and 38b of the thin film transistor 201 are formed by etching a portion of a microcrystalline silicon film formed on the semiconductor layer 36 that is located over a region that becomes the channel region of the semiconductor layer 36. When the etching is performed, the portion of the semiconductor layer 36 to become the channel region, i.e., the surface of a portion that is not covered by either the source electrode 10 or the drain electrode 11, is also etched. Therefore, the thickness Dc of the channel region 36c of the semiconductor layer 36 is smaller than the thicknesses Da and Db of other regions of the semiconductor layer 36 (the source region 36a and the drain region 36b).

Characteristics of μc-Si Thin Film Transistor of Comparison Example 1

First, a μc-Si TFT sample of a comparison example 1 is manufactured by a known method using channel etching. The structure of the μc-Si TFT sample of the comparison example 1 is similar to the structure mentioned above with reference to FIG. 3. A channel length L of the μc-Si TFT sample is set at 3 μm, and a channel width W is set at 20 μm. The thickness Da of the source region 36a and the thickness Db of the drain region 36b of the semiconductor layer 36 are both set at 100 nm. The thickness Dc of the channel region 36c becomes smaller than the thickness Da of the source region 36a and the thickness Db of the drain region 36b because of channel etching. Here, the thickness Dc of the channel region 36c is 44 nm.

As a reference example, an a-Si TFT sample is manufactured using a method and materials similar to those of the μc-Si TFT sample of the aforementioned comparison example 1 except that a semiconductor layer 36 is formed using an amorphous silicon film instead of a microcrystalline silicon film. A channel length L, a channel width W, thicknesses Da, Db, and Dc of the semiconductor layer of the a-Si TFT sample of the reference example are substantially the same as the channel length L, the channel width W, the thicknesses Da, Db, and Dc of the semiconductor layer of the μc-Si TFT sample of the comparison example 1.

Next, characteristics of gate voltage-drain current (Vgd-Isd) of the μc-Si TFT sample of the comparison example 1 and the a-Si TFT sample of the reference example are measured. The measurement is conducted in a darkroom at room temperature (23° C.).

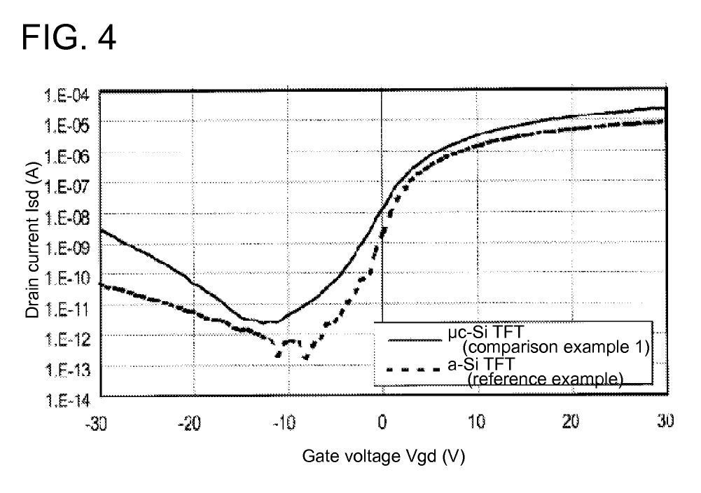

Measurement results are shown in FIG. 4. The horizontal axis of the graph represents potentials of a gate electrode (gate voltage) Vgd based on potentials of a drain electrode. The vertical axis of the graph represents a drain current Isd.

As seen in FIG. 4, in the μc-Si TFT sample of the comparison example 1, not only ON currents but also OFF currents are higher than those of the a-Si TFT sample of the reference example. This is because the mobility of microcrystalline silicon is higher than the mobility of amorphous silicon. The minimum value of OFF currents (minimum OFF current) of the a-Si TFT sample of the reference example is approximately 0.2 pA in the proximity of Vgd=−8V, and this value is a low value that is close to the measuring limit of a measuring device. On the other hand, the minimum OFF current of the μc-Si TFT sample of the comparison example 1 is approximately 2 pA in the proximity of Vgd=−13V.

From this, it can be said that in a microcrystalline silicon TFT, ON currents can be higher than that of an amorphous silicon TFT, but OFF currents also increase. Thus, it can be confirmed that lowering the OFF currents is the problem of the microcrystalline silicon TFT.

Dispersion in TFT Characteristics in Substrate Plane of Comparison Example 1

A substrate having the substrate plane size of 320 mm×400 mm is used as a substrate 1. On the substrate 1, a number of μc-Si TFTs having the same structure as the thin film transistor 201 described above with reference to FIG. 3 are manufactured. The channel length L, the channel width W, the thicknesses Da and Db of the source region 36a and of the drain region 36b of these TFTs are set at 3 μm, 20 μm, and 100 nm, respectively. When forming these TFTs, channel etching conditions are appropriately selected such that the thickness Dc of the channel region 36c becomes approximately 40 nm.

Then, the substrate 1 is divided into 16 blocks (in-plane blocks No. 1 to 16), and one TFT for measurement is selected from the respective blocks. Characteristics of the total of 16 selected TFTs are measured, and a distribution of TFT characteristics in a substrate plane is studied. The measurements are conducted in a darkroom at room temperature (23° C.).

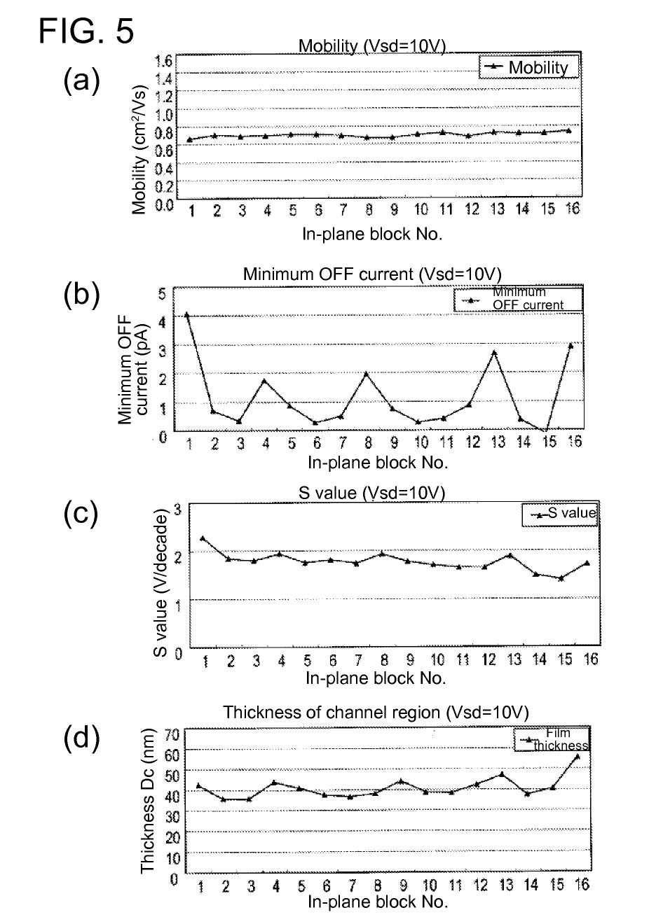

Measurement results are shown in FIG. 5(a) to FIG. 5(d). FIG. 5(a), FIG. 5(b), FIG. 5(c), and FIG. 5(d) are graphs respectively showing distributions of mobility of TFT, minimum OFF current, S value, and thickness Dc of the channel region 36c of the semiconductor layer 36 in a substrate plane. The horizontal axes of these graphs are numbers representing in-plane blocks of the substrate 1.

As shown in FIG. 5(a), the mobility of TFTs formed in the respective blocks of the substrate 1 is relatively constant, and is distributed around approximately 0.7 cm²/Vs. On the other hand, as shown in FIG. 5(b), the minimum OFF current varies greatly in the substrate plane. Specifically, TFTs formed in in-plane blocks No. 1, 4, 8, 13, and 16 have higher minimum OFF currents than other TFTs. Similarly, as shown in FIG. 5(c), the S value of TFTs formed in in-plane blocks No. 1, 4, 8, 13, and 16 is higher than the S value of TFTs formed in other blocks. Further, the thickness Dc of the channel region 36c of TFTs formed in in-plane blocks No. 1, 4, 9, 13, and 16 is greater than the thickness Dc of the channel region 36c of TFTs formed in other blocks. From these results, although the dispersion in the thickness Dc of the channel region 36c in the substrate plane does not fully match the dispersion in TFT characteristics (the minimum OFF current and the S value), it can be considered that they have a correlation.

Relation of Thickness Dc of Channel Region and TFT Characteristics of μc-Si TFT of Comparison Example 1

A number of μc-Si TFTs that have a structure similar to that of the thin film transistor 201 described above with reference to FIG. 3 and that have a mutually different thickness Dc of the channel region 36c of the semiconductor layer 36 are manufactured. The channel length L, the channel width W, the thicknesses Da and Db of the source region 36a and the drain region 36b of these TFTs are set at 3 μm, 20 μm, and 100 nm, respectively.

Characteristics of the aforementioned μc-Si TFT are measured, and a relation between TFT characteristics and the thickness Dc of the channel region 36c is studied.

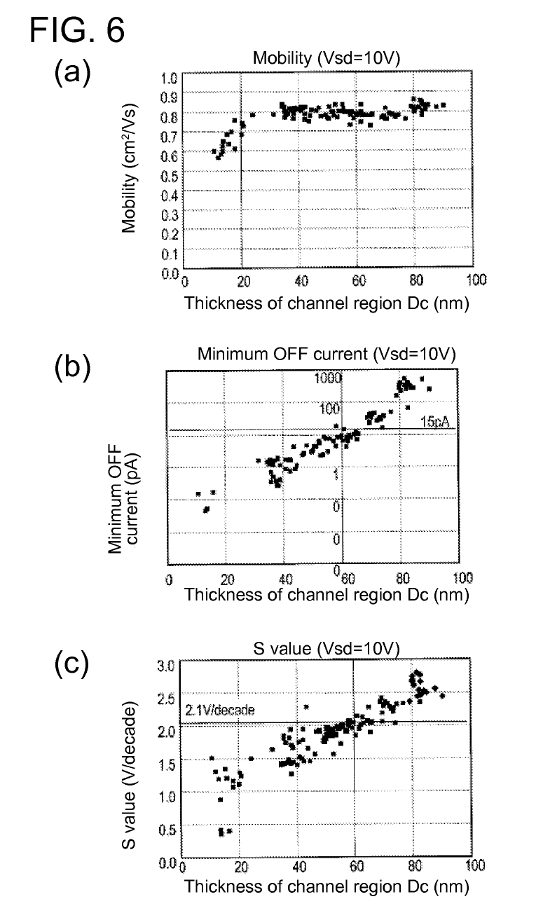

Results are shown in FIG. 6. FIG. 6(a), FIG. 6(b), and FIG. 6(c) are graphs respectively showing the relations of the thickness Dc of the channel region 36c of a TFT with the mobility of the TFT, the minimum OFF current, and the S value. All of the horizontal axes of these graphs represent the thickness Dc of the channel region 36c.

Based on the results shown in FIG. 6(a), it can be said that the mobility is substantially constant if the thickness Dc of the channel region 36c is 20 nm or more, and that the mobility decreases if it becomes less than 20 nm. Further, as shown in FIG. 6(b), it can be said that the minimum OFF current can be suppressed to be within an acceptable range (15 pA or less, for example) if the thickness Dc of the channel region 36c is 60 nm or less. Similarly, as shown in FIG. 6(c), if the thickness Dc of the channel region 36c is 60 nm or less, the S value can be suppressed to be in an acceptable range (2.1V/decade or less, for example).

Based on the results shown in FIG. 6, it can be said that a high mobility (ON characteristics) and a low OFF current (minimum OFF current) can coexist if the thickness Dc of the channel region 36c is 20 nm or more and 60 nm or less.

As shown in the measurement results above of the comparison example 1, in order to achieve high TFT characteristics, the thickness Dc of the channel region 36c of the TFT needs to be controlled to be within a prescribed range. Furthermore, in order to suppress uneven TFT characteristics in the substrate plane, reducing uneven thickness Dc of the channel region 36c is important.

Above, a preferable range of the thickness Dc of the channel region 36c of an inverted staggered channel etching type microcrystalline silicon TFT was studied. Because of similar reasons, it is preferable to control the thickness Dc of the channel region to be 20 nm or more and 60 nm or less in an inverted staggered channel oxidization type microcrystalline silicon TFT as well. This way, OFF currents can be reduced while securing a high mobility.

In an amorphous silicon TFT, the minimum OFF current hardly depends on the thickness Dc of the channel region. If the thickness Dc of the channel region is at least 100 nm or less, the minimum OFF current becomes constant at a low value. Since the thickness Dc of the channel region of a conventional amorphous silicon TFT can have a wider range, even if there is a distribution of the thickness Dc of a channel region in a similar substrate plane, it does not become a problem in particular. Therefore, there is no need to control the thickness Dc of the channel region to be within the aforementioned narrow range.

Method for Manufacturing Thin Film Transistor 101

Next, with reference to figures, an example of a method for manufacturing a thin film transistor 101 of a semiconductor device according to the present embodiment is described in more detail. The thin film transistor 101 is manufactured by following the steps S301 to S305 described above with reference to FIG. 2.

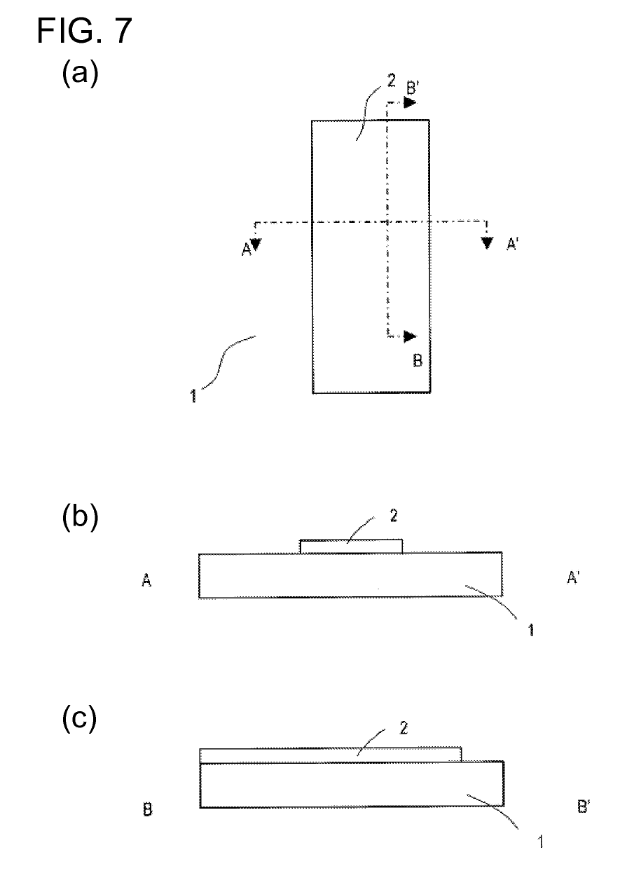

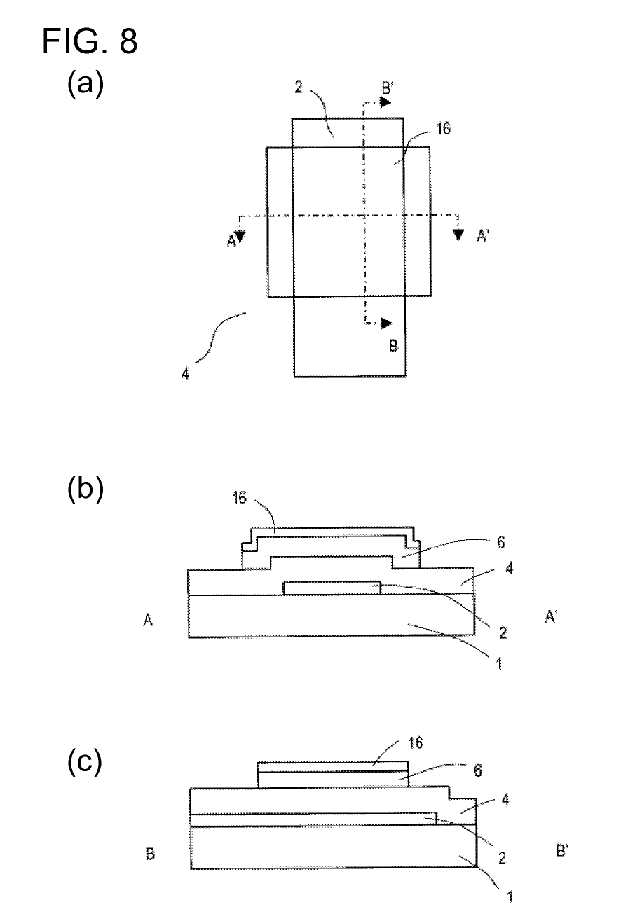

FIGS. 7 to 10 are schematic drawings for explaining the respective steps S301 to S305 for manufacturing the thin film transistor 101. FIG. 7(a) is a plan view. FIG. 7(b) is a cross-sectional view taken along the line A-A′ of FIG. 7(a). FIG. 7(c) is a cross-sectional view taken along the line B-B′ of FIG. 7(a). FIGS. 8 to 10 are similar to these. In each figure, (a) is a plan view, and in each figure, (b) and (c) are cross-sectional views taken along the lines A-A′ and B-B′ of the corresponding plan view, respectively.

(1) Gate Electrode Formation Step S301

As shown in FIG. 7(a) to FIG. 7(c), a gate metal film is formed on a substrate 1, and is patterned to form a gate electrode 2 of the thin film transistor 101.

Specifically, first, by a sputtering method using an Argon (Ar) gas, a tantalum nitride (TaN) of 50 nm thick, a tantalum (Ta) of 200 nm thick, and a tantalum nitride of 50 nm thick are successively deposited on the substrate 1, such as a glass substrate or the like, to form a gate metal film (not shown in the figure), which is a TaN/Ta/TaN multilayer film. The temperature of the substrate 1 when the gate metal film is formed is set at 200 to 300° C. When the tantalum nitride is deposited, a nitrogen gas is used in addition to the argon gas to deposit the tantalum nitride by a reactive sputtering method.

Next, a resist pattern film (not shown in the figure) made of a photoresist material is formed on the gate metal film. Using this resist pattern film as a mask, the gate metal film is patterned (photolithography step). This way, the gate electrode 2 is obtained. For etching the gate metal film, a dry etching method using a carbon tetrafluoride (CF₄) gas and oxygen (O₂) gas, for example, is used. After etching, the resist pattern film is removed using a remover liquid containing an organic alkali.

Besides tantalum (Ta), the material for the gate metal film may be indium tin oxide (ITO), an elemental metal, such as tungsten (W), copper (Cu), chrome (Cr), molybdenum (Mo), aluminum (Al), titanium (Ti), or the like, or a material made by including nitrogen, oxygen, or another metal in such a metal. The gate metal film may be a single layer using the aforementioned material, or may have a multilayer structure. The gate electrode 2 may be a Ti/Al/Ti multilayer film formed of titanium and aluminum, a Ti/Cu/Ti multilayer film formed of titanium and copper, or a Mo/Cu/Mo multilayer film formed of copper and molybdenum, for example.

As a method for forming the gate metal film, a vapor deposition method or the like may be used besides the sputtering method. The thickness of the gate metal film is not particularly limited. Furthermore, the etching method of the gate metal film is not limited to the aforementioned dry etching method, and a wet etching method using an acid or the like as an etchant, or the like, may be used.

(2) Gate Insulating Layer and Semiconductor Layer Formation Step S302

Next, on the gate electrode 2, a gate insulating layer 4, a microcrystalline silicon film, and an n⁺ type microcrystalline silicon film are formed in this order, and the microcrystalline silicon film and the n⁺ type microcrystalline silicon film are patterned. This way, as shown in FIG. 8(a) to FIG. 8(c), a semiconductor layer 6 and an n⁺ type microcrystalline silicon layer 16 that have an island-shape in its planar shape are obtained.

The gate insulating layer 4, the microcrystalline silicon film, and the n⁺ type microcrystalline silicon film are formed continuously in a vacuum using a multi-chamber type device.

The gate insulating layer 4 can be formed under the same film formation conditions as a manufacturing process of a conventional a-Si TFT. Specifically, first, on the substrate 1 having the gate electrode 2 formed thereon, the gate insulating film 4 (thickness: 400 nm, for example) made of silicon nitride (SiNₓ) is formed by a plasma CVD method. In the present embodiment, the gate insulating layer 4 is formed using a plasma CVD of a CCP method (capacitively coupled type) under conditions of the substrate temperature of 250 to 300° C. and the pressure of 50 to 300 Pa. As gasses for the film formation, silane (SiH₄), ammonia (NH₃), and nitrogen (N₂) are used.

Next, the substrate is transported to a different chamber in a vacuum to form a microcrystalline silicon film (thickness: 30 nm, for example). The CVD used is a high-density plasma CVD (ICP method, surface wave plasma method, or ECR method), and it is conducted under conditions of the substrate temperature of 250 to 300° C. and the pressure of approximately 1.33 Pa. As gasses for the film formation, silane (SiH₄) and hydrogen (H₂) are used. The ratio of flow volumes of silane and hydrogen is set at 1:20. Before forming the microcrystalline silicon film, the gate insulating layer 4 may be subjected to a surface treatment such as a hydrogen plasma treatment or the like. In that case, the pressure is set at approximately 1.33 Pa.

Then, the substrate is transported to another chamber in a vacuum, and an n⁺ type microcrystalline silicon film (thickness: 10 nm, for example) is formed using a similar high-density plasma CVD. In the present embodiment, the n⁺ type microcrystalline silicon film is formed in a manner substantially similar to the microcrystalline silicon film. The difference is that as the gasses for the film formation, silane (SiH₄), hydrogen (H₂), and phosphine (PH₃) are used.

Then, on the n⁺ type microcrystalline silicon film, a resist pattern film (not shown in the figure) made of a photoresist material is formed, and the microcrystalline silicon film and the n⁺ type microcrystalline silicon film are patterned (photolithography step) using the resist pattern film as a mask. This way, as shown in FIG. 8(a) to FIG. 8(c), the semiconductor layer 6 and the n⁺ type microcrystalline silicon layer 16 having an island-shape in its planar shape are obtained. For etching the microcrystalline silicon film and the n⁺ type microcrystalline silicon film, a dry etching method that mainly uses a chlorine (Cl₂) gas, for example, is used. After etching, the resist pattern film is removed using a remover liquid containing an organic alkali.

The thickness of the n⁺ type microcrystalline silicon layer 16 is not particularly limited; however, it is preferably 3 nm or more and 30 nm or less, for example. This is because if it is 3 nm or more, it does not lower ON currents of the TFT when used in a contact region. On the other hand, if the n⁺ type microcrystalline silicon layer 16 is 30 nm or less, or more preferably, 10 nm or less, it is oxidized with ease by the oxidization treatment (plasma oxidization) that is discussed layer, and the separation region 9 formed of an oxidized silicon film can be formed securely. More preferably, the thickness is 10 nm or less.

The n⁺ type microcrystalline silicon film, which becomes the n⁺ type microcrystalline silicon layer 16, may be formed under the conditions similar to those for the microcrystalline silicon film, which becomes the semiconductor layer 6, except that a gas containing phosphine is used as a gas for film formation. As described above, when an n⁺ type microcrystalline silicon film is formed using a microcrystalline silicon film as a base, the n⁺ type microcrystalline silicon film is affected by the base, and the volume fraction of its crystalline phase becomes higher than the volume fraction of the crystalline phase of the microcrystalline silicon film.

Alternatively, the volume fraction of the crystalline phase of the n⁺ type microcrystalline silicon film can be further increased by appropriately selecting film formation conditions of the n⁺ type microcrystalline silicon film. If these films are formed using the plasma CVD mode, for example, when the n⁺ type microcrystalline silicon film is formed, the high-frequency (RF) power and the total flow volume of gasses for film formation can be reduced compared to those used when the microcrystalline silicon film is formed. This way, the electrical resistance of contact regions 8a and 8b formed of the n⁺ type microcrystalline silicon film can be reduced further while keeping OFF currents low. When the electrical resistance of the contact regions 8a and 8b, which becomes parasitic resistance of the TFT, is reduced, ON currents of the TFT increase. As a result, high TFT characteristics can be achieved. The volume fraction of the crystalline phase of the contact regions 8a and 8b may be higher than the volume fraction of the crystalline phase of a surface portion (surface portion of the side on which an incubation layer is not formed) of the semiconductor layer 6. In that case, although it depends on the density of microcrystals in the respective layers 6 and 8, the average grain size of microcrystals of the contact regions 8a and 8b becomes larger than the average grain size of the microcrystals of the semiconductor layer 6, for example.

Alternatively, the volume fraction of the crystalline phase of the n⁺ type microcrystalline silicon film may be reduced (to 60% or more and 85% or less, for example) by increasing the high-frequency (RF) power or by increasing the total flow volume of the gasses for film formation when the n⁺ type microcrystalline silicon film is formed. This way, the ratio of crystal grain boundaries included in the n⁺ type microcrystalline silicon film becomes larger. As a result, in the oxidization treatment, which is discussed later, the separation region 9 can be formed of a more uniform oxidized silicon film by oxidizing these crystal grain boundaries, and only the n⁺ type microcrystalline silicon film can be selectively oxidized more securely. Film formation conditions of the microcrystalline silicon film and the n⁺ type microcrystalline silicon film may be adjusted so that the volume fraction of the crystalline phase of the n⁺ type microcrystalline silicon film becomes lower than the volume fraction of the crystalline phase in a surface portion of the microcrystalline silicon film, which becomes the base. In that case, although it depends on the density of microcrystals of the respective films, the average grain size of microcrystals of the contact regions 8a and 8b formed of the n⁺ type microcrystalline silicon film becomes smaller than the average grain size of microcrystals of the semiconductor layer 6 formed of the microcrystalline silicon film, for example.

(3) Source and Drain Electrodes Formation Step S303

Over the n⁺ type microcrystalline silicon layer 16 and the gate insulating layer 4, a metal film for forming source and drain electrodes is formed. In the present embodiment, a 100 nm-thick molybdenum (Mo) and a 100 nm-thick aluminum (Al), for example, are successively deposited on a surface of the substrate 1 by a sputtering method using an argon (Ar) gas to form a metal film (thickness: 200 nm), which is an Al/Mo multilayer film. The substrate temperature when the metal film is formed is set at 200 to 300° C.

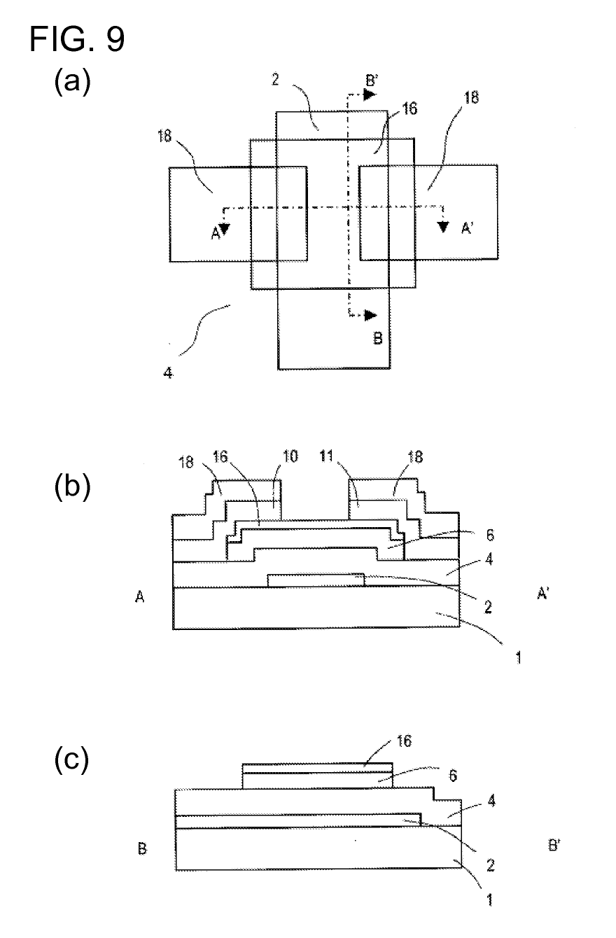

Then, as shown in FIG. 9(a) to FIG. 9(c), a resist pattern film 18 is formed on the metal film. Using this as a mask, the metal film is patterned to obtain a source electrode 10 and a drain electrode 11 of the thin film transistor 101.

Etching of the metal film can be conducted using a wet etching method, for example. In the present embodiment, an aqueous solution containing a phosphoric acid, a nitric acid, and an acetic acid is used as an etchant. The resist pattern film 18 is not removed after etching, and is left until the following step.

Other than molybdenum (Mo), the material for the metal film may be indium tin oxide (ITO), an elemental metal, such as tungsten (W), copper (Cu), chrome (Cr), tantalum (Ta), aluminum (Al), titanium (Ti), or the like, or a material made by including nitrogen, oxygen, or another metal in such a metal. The source electrode 10 and the like may be a single layer using the aforementioned material, or may have a multilayer structure. The metal film may be a Ti/Al/Ti multilayer film formed of titanium and aluminum, a Ti/Cu/Ti multilayer film formed of titanium and copper, or a Mo/Cu/Mo multilayer film formed of copper and molybdenum, for example.

As a method for forming the metal film, other than the sputtering method, a vapor deposition method or the like may be used. Also, the method for forming the metal film is not limited to the wet etching using the aforementioned etchant either. Furthermore, the thickness of the metal film is not limited to the aforementioned thickness.

(4) Source and Drain Electrodes Separation Step S304

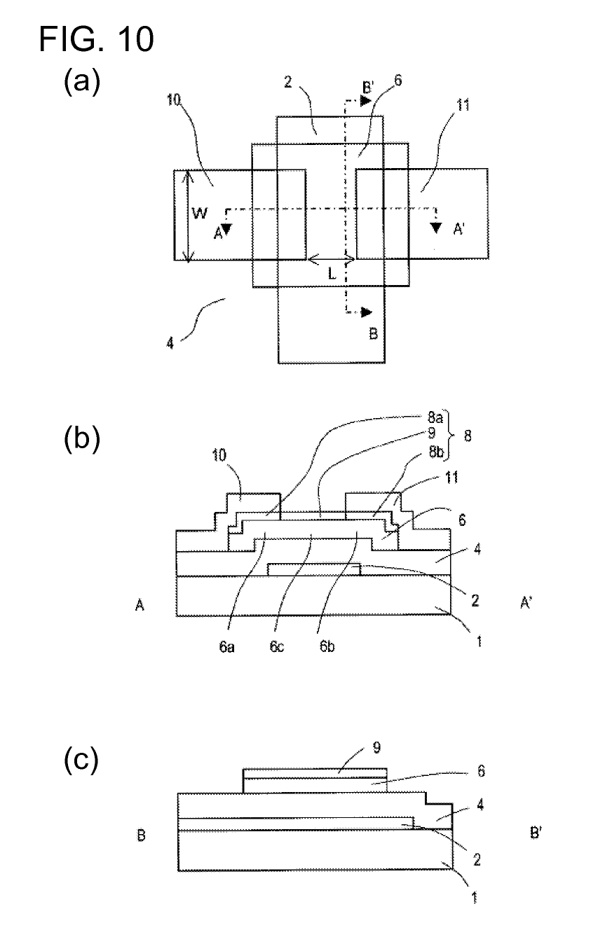

Then, as shown in FIG. 10(a) to FIG. 10(c), a portion of the n⁺ type microcrystalline silicon layer 16 that is not covered by either the source electrode 10 or the drain electrode 11 (exposed portion) is oxidized. This way, an oxidized silicon layer (separation region) 9 of approximately 10 nm in thickness is formed. A portion of the n⁺ type microcrystalline silicon layer 16 that was not oxidized becomes contact regions 8a and 8b. This way, a contact formation layer 8 is obtained. Thus, the source electrode 10 and the drain electrode 11 can be disconnected from each other appropriately. Oxidization treatment conditions, such as temperature, time, and the like, are appropriately set so that the semiconductor layer 6 is not oxidized or so that only the surface portion of the semiconductor layer 6 is oxidized.

The thickness of the contact formation layer 8 is substantially the same as the thickness of the n⁺ type microcrystalline silicon layer 16, and is 3 nm or more and 30 nm or less (10 nm here), for example.

In the present embodiment, plasma oxidization is performed using an ICP mode dry etching device as a high-density plasma device. The substrate temperature is set at 60° C. By exposing the substrate 1 to oxygen (O₂) plasma, the exposed portion of the n⁺ type microcrystalline silicon layer 16 is oxidized.

The plasma device used in this step is not limited to the ICP method and to the dry etching device. A plasma device of another high-density plasma method (surface wave plasma method or ECR method) may be used, or a CCP method (capacitively coupled type) may be used. Alternatively, because the oxidization treatment is not required to be performed in a vacuum chamber, an atmospheric-pressure plasma device may be used. Plasma oxidization and UV treatment or ozone treatment may be combined. Alternatively, only one of plasma oxidization, UV treatment, and ozone treatment may be performed. Alternatively, the exposed portion of the n⁺ type microcrystalline silicon layer 16 may be oxidized by performing a thermal treatment at approximately 250 to 300° C. in an atmosphere containing oxygen gas.

The resist pattern film 18 may be removed in the step of forming the aforementioned separation region 9, or may be removed using a remover liquid containing an organic alkali after the separation region 9 has been formed.

(5) Passivation Layer Formation Step S305

Next, a passivation layer 14 formed of silicon nitride (SiNₓ) is formed to cover the source electrode 10, the drain electrode 11, the separation region 9, and the periphery of them. As a result, the thin film transistor 101 shown in FIG. 1(a) to FIG. 1(c) is obtained.

Specifically, the passivation layer 14 (thickness: 250 nm, for example) formed of silicon nitride (SiNₓ) is formed by a plasma CVD method. In the present embodiment, the passivation layer 14 is formed using a CCP plasma CVD under the conditions of the substrate temperature of 250 to 300° C. and the pressure of 50 to 300 Pa. As the gasses for film formation, silane (SiH₄), ammonia (NH₃), and nitrogen (N₂) are used.

Although not shown in the figure, in order to establish an electrical connection to the source electrode 10, the drain electrode 11, and the gate electrode 2 of the thin film transistor 101, respectively, contact holes are provided in the gate insulating layer 4 and the passivation layer 14.

Structure of Semiconductor Device

The thin film transistor 101 shown in FIG. 1(a) to FIG. 1(c) is suitably used in an active matrix substrate of a display device, for example.

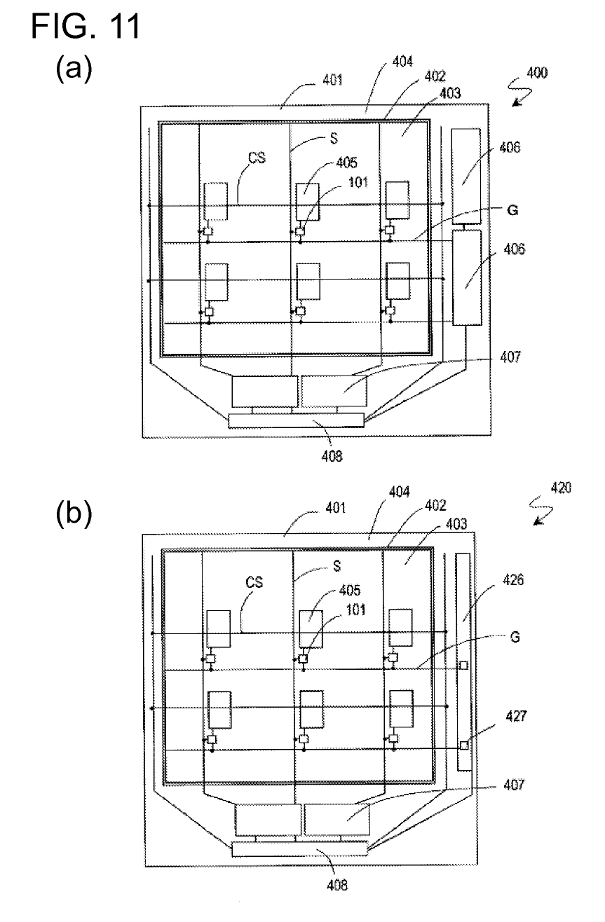

FIG. 11(a) is a schematic top view of an active matrix substrate according to the present embodiment.

An active matrix substrate 400 has a display region 403 that includes a plurality of pixels and a peripheral region 404 provided in the periphery of the display region 403. In FIG. 11(a), the border between the display region 403 and the peripheral region 404 is represented by a double line 402.

In the display region 403, a plurality of thin film transistors 101, which are used as pixel TFTs, a gate wire G that is electrically connected to the gate electrode of the thin film transistor 101, a source wire S that is electrically connected to the source electrode of the thin film transistor 101, a plurality of pixel electrodes 405 that are electrically connected to the drain electrodes of the respective thin film transistors 101, and an auxiliary capacitance wire CS for providing an auxiliary capacitance to the pixel electrodes 405 are provided. As an electrode for providing an auxiliary capacitance, a portion of the auxiliary capacitance wire CS is used as an electrode. The thin film transistor 101 has a structure that was described above with reference to FIG. 1.

In the peripheral region 404, a gate driver IC mounting portion 406 for mounting a gate driver IC (Integrated Circuit) that applies scan signals to the gate wire G, a source driver IC mounting portion 407 for mounting a source driver IC (Integrated Circuit) that applies image signals to the source wire, and a connection terminal portion 408 for inputting power supply and signals from outside to the source driver IC, the gate driver IC, the auxiliary capacitance wire CS, and the like are provided.

The thin film transistor 101 of the present embodiment has a high mobility because it uses microcrystalline silicon for the active layer. Furthermore, it is suitable for a large active matrix substrate, such as a large-screen television or the like, because it can be formed uniformly in the substrate plane. When the active matrix substrate 400 of the present embodiment is used in a display device, the display device having high performance, such as, higher resolution, lower energy consumption, and faster display, can be achieved.

FIG. 11(b) is a schematic top view of another active matrix substrate according to the present embodiment. For convenience, components similar to those in the active matrix substrate 400 shown in FIG. 11(a) are given the same reference characters, and their description is omitted.

An active matrix substrate 420 includes a monolithic gate driver 426 that is integrally formed on a substrate 401 at the location of the gate driver IC mounting portion 406. The monolithic gate driver 426 has circuit TFTs (not shown in the figure). The circuit TFT has a similar film structure to a thin film transistor 101 formed in a display region 403. “Having a similar film structure” means that a gate electrode, a semiconductor layer, a contact formation layer, an interlayer insulating layer, and the like of the circuit TFT are formed using the same film as the respective layers of the thin film transistor 101. Design values, such as the channel length, the channel widths, and the like may be different from each other.

The circuit TFT according to the present embodiment has a high mobility because it uses microcrystalline silicon for the active layer. Furthermore, since it can be formed uniformly in the substrate plane, it can be suitably used in a monolithic gate driver as well.

The active matrix substrate of the present embodiment may have a source division driver circuit that is disclosed in Japanese Patent Application Laid-Open No. 2005-115342, for example.

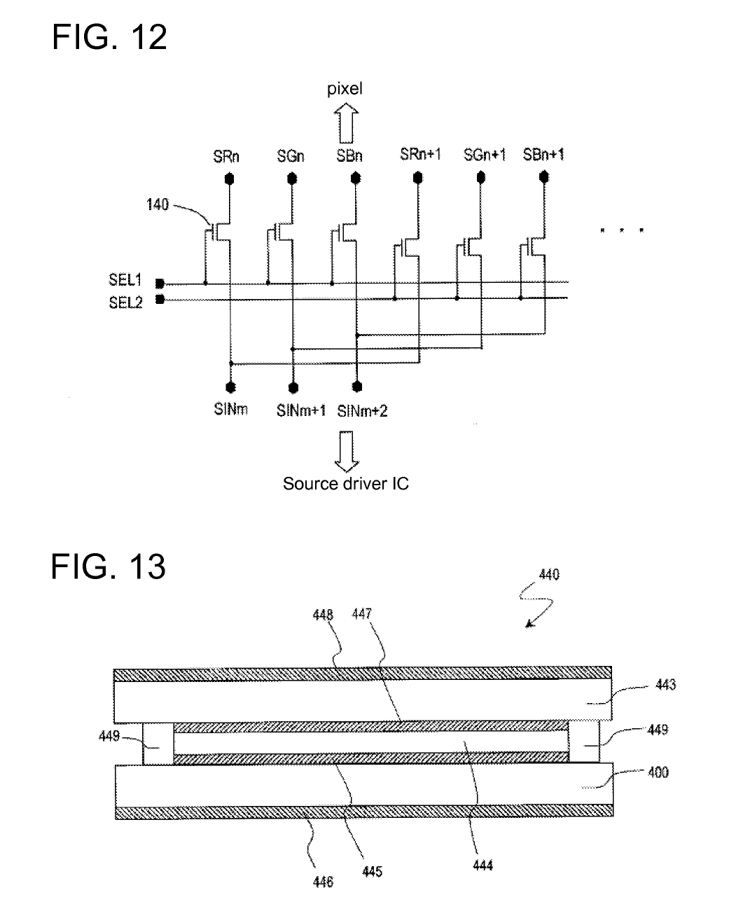

FIG. 12 shows an example of a source division driver circuit according to the present embodiment. On the display region side, adjacent source wires SRn, SGn, SBn, SRn+1, SGn+1, and SBn+1 are disposed. On the source driver IC side, driver wires SINm, SINm+1, and SINm+2 are disposed. Using switching signals supplied by SEL1 or SEL2 and a thin film transistor 140, the source division driver circuit divides signals supplied to SINm and the like from the source driver IC into SRn, SRn+1, or the like. As to SINm+1 and SINm+2, the function is similar. The thin film transistor 140 has a structure that was described above with reference to FIG. 1.

The thin film transistor 140 has high ON currents because it uses microcrystalline silicon for the active layer. Thus, the area of the circuit can be reduced, and a narrower frame of a semiconductor device can be achieved.

The active matrix substrates 400 and 420 of the present embodiment are suitably used in a liquid crystal display device, for example. FIG. 13 is a schematic cross-sectional view of a liquid crystal panel 440 using the active matrix substrate 400 of the present embodiment.

As shown in FIG. 13, the liquid crystal panel 440 according to the present embodiment is equipped with an active matrix substrate (also referred to as a first substrate) 400, a liquid crystal layer 444, and an opposite substrate (also referred to as a second substrate) 443 that is disposed to face the active matrix substrate 400 through the liquid crystal layer 444. The liquid crystal layer 444 is sealed by a sealing material 449 that is interposed between the active matrix substrate 400 and the opposite substrate 443.

An alignment film 445 is provided on a surface of the active matrix substrate 400 on the liquid crystal layer 444 side, and an alignment film 447 is provided on a surface of the opposite substrate 443 on the liquid crystal layer 444 side. Meanwhile, a polarizing plate 446 is provided on the active matrix substrate 400 on a surface that is on the opposite side from the liquid crystal layer 444, and a polarizing plate 448 is provided on the opposite substrate 443 on a surface that is on the opposite side from the liquid crystal layer 104.

Although not shown in the figure, a plurality of pixels are provided on the active matrix substrate 400, and a TFT, which is a switching element shown in FIG. 1, is formed for each pixel. Moreover, on the active matrix substrate 400, a source driver IC and a gate driver IC (not shown in the figure) for controlling drive of the respective TFTs are mounted. Although not shown in the figure, on the opposite substrate 443, a color filter and a common electrode of ITO are formed.

A liquid crystal display device according to the present embodiment is equipped with a backlight unit and another circuit board (not shown in the figure), in addition to such a liquid crystal panel 440. Instead of the active matrix substrate 400, the active matrix substrate 420 shown in FIG. 11(b) may be used. In that case, there is no need to mount a gate driver IC on the active matrix substrate 420.

The structure and manufacturing method of a thin film transistor according to the present embodiment are not limited to the structure and manufacturing method described above with reference to FIG. 1 and FIGS. 7 to 10. In order to securely disconnect the source electrode from the drain electrode, when a portion of an n⁺ type microcrystalline silicon film is oxidized to form a separation region in the channel oxidization step, a surface portion of a semiconductor layer (microcrystalline silicon film) that is located below the n⁺ type microcrystalline silicon film may be oxidized. The structure of a thin film transistor obtained this way is described below.

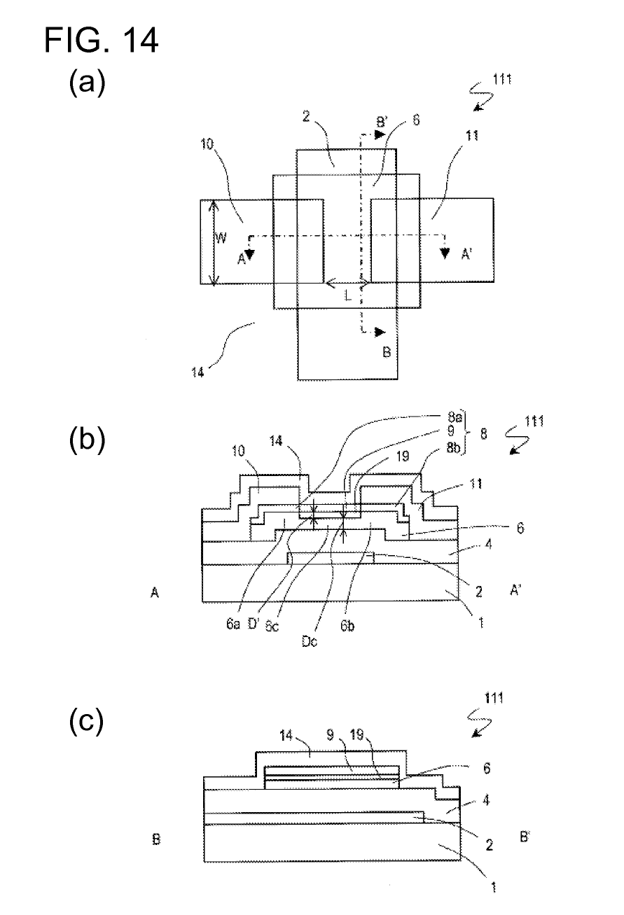

FIG. 14(a) to FIG. 14(c) schematically show another thin film transistor according to the present embodiment. FIG. 14(a) is a plan view. FIG. 14(b) and FIG. 14(c) are cross-sectional views taken along the line A-A′ and the line B-B′ of FIG. 14(a), respectively. For convenience, components similar to those of the thin film transistor 101 shown in FIG. 1(a) are given the same reference characters, and description is omitted.

As shown in FIG. 14(a) to FIG. 14(c), in an thin film transistor 111, an oxidized silicon layer 19 is formed between a separation region (oxidized silicon layer) 9 of a contact formation layer 8 and a channel region 6c.

The separation region 9 is formed of a film that is obtained by oxidizing an n⁺ type microcrystalline silicon film for forming contact regions 8a and 8b, and contains a dopant (here, phosphorus). In contrast, the oxidized silicon layer 19 essentially does not contain a dopant because it is formed of a film obtained by oxidizing a microcrystalline silicon film for forming a semiconductor layer 6.

The thickness D′ of the oxidized silicon layer 19 needs to be smaller than the thicknesses of the semiconductor layer 6 (thickness of a source region 6a and thickness of a drain region 6b) Da and Db. The thickness D′ of the oxidized silicon layer 19 is preferably limited to 10 nm or less at a chosen location in the substrate. This way, uneven thickness Dc of the channel region 6c (the largest difference in film thickness in the substrate plane) caused by channel separation (here, formation of the oxidized silicon layer 19) can be limited to 10 nm or less, and a plurality of TFTs having uniform characteristics in the substrate plane can be manufactured securely. In the present embodiment, the thicknesses Da and Db of the semiconductor layer 6 are 40 nm, the thickness Dc of the channel region 6c of the semiconductor layer 6 is 30 nm, and the thickness D′ of the oxidized silicon layer 19 is 10 nm maximum in the substrate plane.

The thin film transistor 111 can be manufactured by a method similar to that of the thin film transistor 101 described above with reference to FIGS. 7 to 10. However, in the source and drain electrodes separation step shown in FIG. 10, not only the n⁺ type microcrystalline silicon layer 16 (FIG. 9), but also a surface of the semiconductor layer 6 below are oxidized. Here, oxidization treatment conditions are appropriately adjusted so that the thickness Dc of the channel region 6c becomes a desired thickness (here, 30 nm).

As described, the thickness Dc of the channel region 6c can be reduced further (to 30 nm or less, for example) by additionally oxidizing up to the surface of the semiconductor layer 6. Because of this, OFF currents of the thin film transistor 111 can be reduced more effectively. Furthermore, reliability can be improved because the source electrode can be disconnected more securely from the drain electrode. Additionally, according to the aforementioned method, defective characteristics caused by channel etching can be suppressed. As a result, a plurality of TFTs having uniform characteristics can be manufactured more securely on the substrate 1. Therefore, the product non-defect rate and mass productivity can be improved.

The semiconductor layer 6 and the contact formation layer 8 may not be island-shaped. When a half-tone exposure is used, for example, the process becomes simpler if the semiconductor layer 6 and the like are not island-shaped. When a half-tone exposure is used, the number of resist pattern film formation can be reduced, and production materials, such as a photoresist material and the like for forming a resist pattern film can be reduced, which are advantageous. A process using the half-tone exposure is discussed, for example, in “SID 2000 Digest,” pages 1006-1009, by C. W. Kim et al. Instead of separately performing patterning using photolithography in the gate insulating layer and semiconductor layer formation step S302 and in the source and drain electrodes formation step S303, for example, performing patterning using the same resist pattern film can be considered as an specific example using the half-tone exposure.

Even when the aforementioned half-tone exposure is used, in the following source and drain electrodes separation step S304, the aforementioned oxidization treatment is performed. Thus, similar effects as the method described above with reference to FIGS. 7 to 10 can be obtained.

### Embodiment 2

Embodiment 2 of a semiconductor device according to the present invention is described below with reference to figures. The semiconductor device of the present embodiment is equipped with a substrate and an inverted staggered type microcrystalline silicon thin film transistor formed on the substrate. The thin film transistor according to the present embodiment is different from the aforementioned thin film transistor 101 of Embodiment 1 in that it is further provided with an amorphous silicon layer that functions as an oxidization stop layer between a channel region and a separation region.

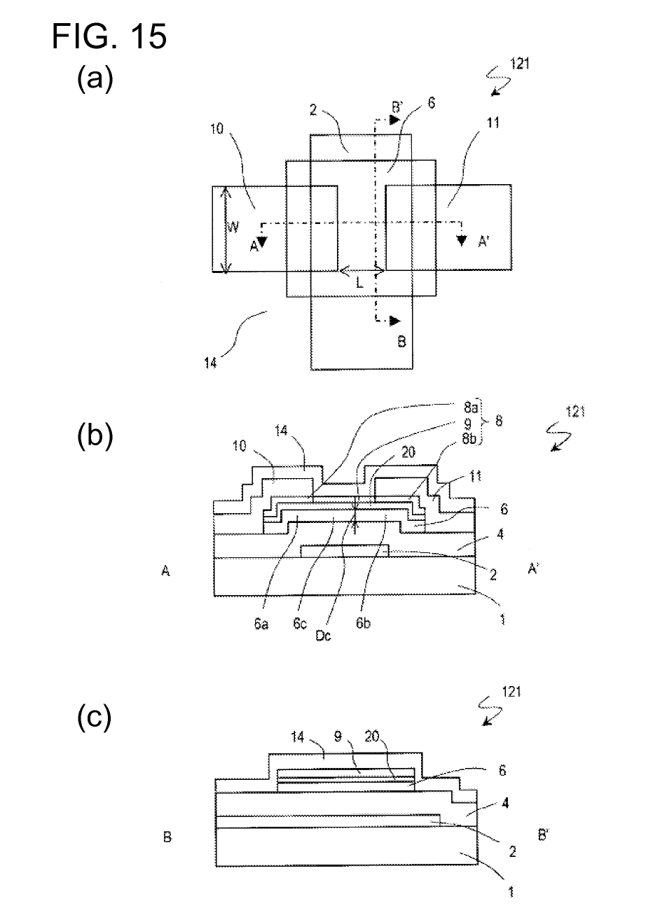

FIG. 15(a) to FIG. 15(c) schematically show a thin film transistor 121 according to the present embodiment. FIG. 15(a) is a plan view of the thin film transistor 121. FIG. 15(b) and FIG. 15(c) are cross-sectional views taken along the line A-A′ and the line B-B′ of FIG. 15(a), respectively. For convenience, components similar to those of the thin film transistor 101 shown in FIG. 1(a) to FIG. 1(c) are given the same reference characters, and description is omitted.

As shown in FIG. 15(a) to FIG. 15(c), the thin film transistor 121 has an amorphous silicon layer 20 between a semiconductor layer 6 and a contact formation layer 8. The amorphous silicon layer 20 functions as an oxidization stop layer in a channel oxidization step when the thin film transistor 121 is manufactured. In the present embodiment, the thickness of the semiconductor layer 6 is 30 nm; the thickness of the amorphous silicon layer 20 is 20 nm; and the thickness of a separation region 9 is 10 nm, for example.

Next, a method for manufacturing the thin film transistor 121 of the present embodiment is described.

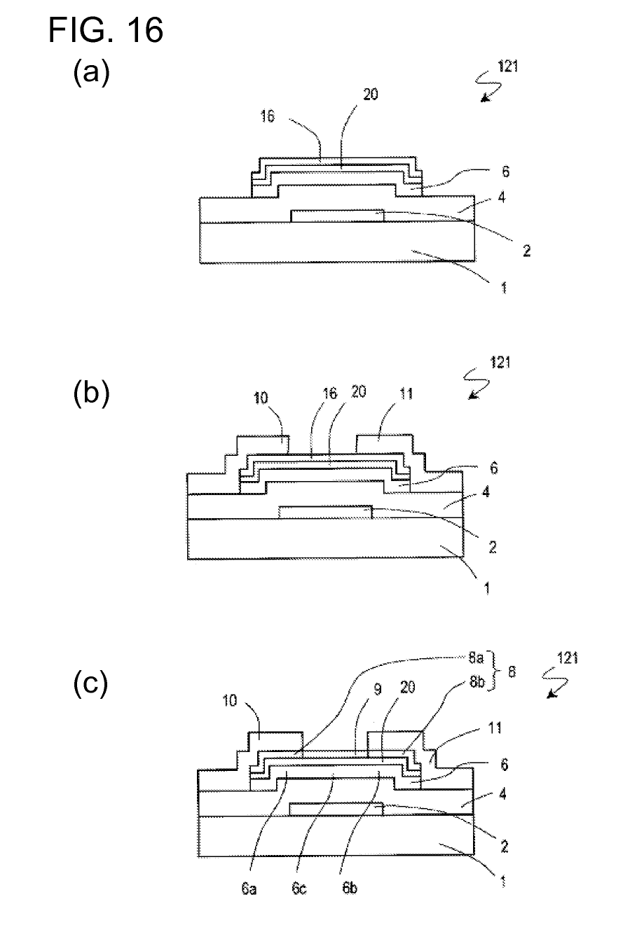

FIG. 16(a) to FIG. 16(c) are schematic process step views showing an example of a method for manufacturing the thin film transistor 121, and show cross-sections along a channel direction. For convenience, components similar to those in FIGS. 7 to 10 are given the same reference characters, and their description is omitted.

First, in a method similar to the method described above with reference to FIGS. 7 and 8, a gate electrode 2 and a gate insulating layer 4 are formed on a substrate 1.

Next, as shown in FIG. 16(a), on the gate insulating layer 4, a microcrystalline silicon film, an amorphous silicon film, and an n⁺ type microcrystalline silicon film are formed in this order using a high-density plasma CVD, for example. Then, these films are patterned. This way, the semiconductor layer (thickness: 30 nm, for example) 6, the amorphous silicon layer (thickness: 20 nm, for example) 20, and an n⁺ type microcrystalline silicon layer (thickness: 10 nm, for example) 16, which have an island-shape in its planar shape, are obtained.

The gate insulating layer 4, the microcrystalline silicon film, the amorphous silicon film, and the n⁺ type microcrystalline silicon film may be formed continuously in a vacuum using a multi-chamber type device. Methods for forming and patterning these films may be similar to the methods described above with reference to FIG. 8. The amorphous silicon film may be formed under the same film forming conditions as those of a manufacturing process of a typical a-Si TFT. Before forming the amorphous silicon film, the microcrystalline silicon film may be subjected to a surface treatment such as a hydrogen plasma treatment or the like.

Next, as shown in FIG. 16(b), a source electrode 10 and a drain electrode 11 are formed on the n⁺ type microcrystalline silicon layer 16. The forming method is similar to the method described above with reference to FIG. 9.

Then, as shown in FIG. 16(c), a portion of the n⁺ type microcrystalline silicon layer 16 that is not covered by either the source electrode 10 or the drain electrode 11 (exposed portion) is oxidized to form the separation region 9. Portions of the n⁺ type microcrystalline silicon layer 16 that are not oxidized become contact regions 8a and 8b, respectively. Conditions for the oxidization treatment are similar to the conditions described above with reference to FIG. 10.

In this process, the n⁺ type microcrystalline silicon layer 16 is oxidized. However, the amorphous silicon layer 20 located below is not oxidized. Alternatively, only the surface of the amorphous layer 20 is oxidized. As described above, the microcrystalline silicon film is oxidized with ease in the thickness-wise direction of the film primarily through the crystal grain boundary portions. In contrast, silicon atoms constituting the inside of the amorphous silicon film are less susceptible to oxidization because, in a manner similar to the silicon atoms inside a crystal or a crystal grain, most of them constitute a network of Si—Si bonds uniformly. In other words, the amorphous silicon film has almost no crystal grain boundaries that the microcrystalline silicon film has, and although the surface of the film is oxidized with ease, continuously oxidizing inside the film is extremely difficult. Therefore, oxidization of the semiconductor layer 6 can be prevented because the amorphous silicon layer 20 functions as an oxidization stop layer. As a result, the thickness Dc of a channel region 6c can be controlled more accurately.

According to the present embodiment, the thickness Dc of the channel region 6c can be controlled more accurately as well as more uniformly in the substrate plane. Therefore, OFF currents of the thin film transistor 121 can be reduced further. In addition, a plurality of TFTs having uniform characteristics can be manufactured on the substrate 1 more securely. Furthermore, the process margin of the channel oxidization step can be increased because the amorphous silicon layer 20 functions as an oxidization stop layer. As a result, the source electrode can be disconnected from the drain electrode more securely.

Furthermore, according to the present embodiment, there are the following advantages compared to a conventional inverted staggered channel etching type TFT.

For example, as shown in FIG. 3, in the thin film transistor 201 formed using channel etching, the surface of the semiconductor layer 6 on the back channel side (opposite side from the substrate 1) is in contact with the passivation layer 14. The surface of the semiconductor layer 6 on the back channel side is exposed to the atmosphere after the completion of channel etching and before formation of the passivation layer (silicon nitride film) 14 begins. Here, in the interface of the semiconductor layer 6 on the back channel side, a naturally oxidized film that is unstable is formed, and the density of defects containing oxygen and the like becomes high. When fixed charges are accumulated in such defects, it becomes a factor to decrease TFT characteristics (particularly, increased threshold and S value). Thus, when a plurality of TFTs are formed on the substrate 1 using channel etching, there has been a problem that TFT characteristics, such as the threshold, the S value, and the like, vary significantly between TFTs in the substrate plane or between substrates, decreasing the production margin.

In contrast, according to the present embodiment, the amorphous silicon film for forming the amorphous silicon layer 20 and the microcrystalline silicon film for forming the semiconductor layer 6 can be deposited continuously in a vacuum. Thus, the thin film transistor 121 can be manufactured without exposing the back channel side surface of the semiconductor layer 6 to the atmosphere. Therefore, the density of defects containing oxygen and the like on the interface of the microcrystalline silicon film on the back channel side can be reduced. As a result, the amount of the fixed charges accumulated in the aforementioned defects can be reduced, and lowering of TFT characteristics, particularly, the threshold, the S value, and the like, can be suppressed.

As described above, according to the present embodiment, the production margin of thin film transistors can be increased. Therefore, the product non-defect rate of a semiconductor device can be increased, and mass productivity can be improved.

Furthermore, according to the present embodiment, there is also an advantage that can suppress driving up of OFF currents. “Driving up of OFF currents” means that, in a deep negative region where the gate voltage (Vgd) is approximately −20V to −30V, for example, OFF currents increase as the Vgd moves towards the negative side. In the conventional TFT shown in FIG. 3, driving up of OFF currents is notably seen.

In the thin film transistor 121 of the present embodiment, the amorphous silicon layer 20 is formed between the semiconductor layer 6 and the contact regions 8a and 8b. In other words, the amorphous silicon layer 20 is located in a main current path between the source electrode 10 and the drain electrode 11. OFF currents of the amorphous silicon layer 20 is lower than OFF currents of the semiconductor layer 6, which is formed of a microcrystalline silicon film. Therefore, a portion of the amorphous silicon layer 20 located between the semiconductor layer 6 and the contact regions 8a and 8b also functions as an electrical resistance that is similar to an LDD (Lightly Doped Drain) structure. As a result, OFF currents of the thin film transistor 121 can be reduced effectively.

Although ON currents are also reduced slightly by the portion of the amorphous silicon layer 20 located between the semiconductor layer 6 and the contact regions 8a and 8b, the ratio of ON currents/OFF currents (ON/OFF ratio) improves. In order to effectively improve the ON/OFF ratio of the thin film transistor 121, the thickness of the amorphous silicon layer 20 preferably is 5 nm or more and 30 nm or less. If the thickness of the amorphous silicon layer 20 exceeds 30 nm, the mobility of the thin film transistor 121 decreases, and ON characteristics degrade. On the other hand, if the thickness of the amorphous silicon layer 20 is less than 5 nm, there may be a risk that OFF currents cannot be reduced more effectively, and that the ON/OFF ratio cannot be improved.

### Embodiment 3

Embodiment 3 of a semiconductor device according to the present invention is described below with reference to figures. The semiconductor device of the present embodiment is an active matrix substrate. An active matrix substrate according to the present embodiment has a display region including a plurality of pixel regions and a peripheral region located in the periphery of the display region. In the peripheral region, a gate driver including a plurality of terminal portion regions is provided.

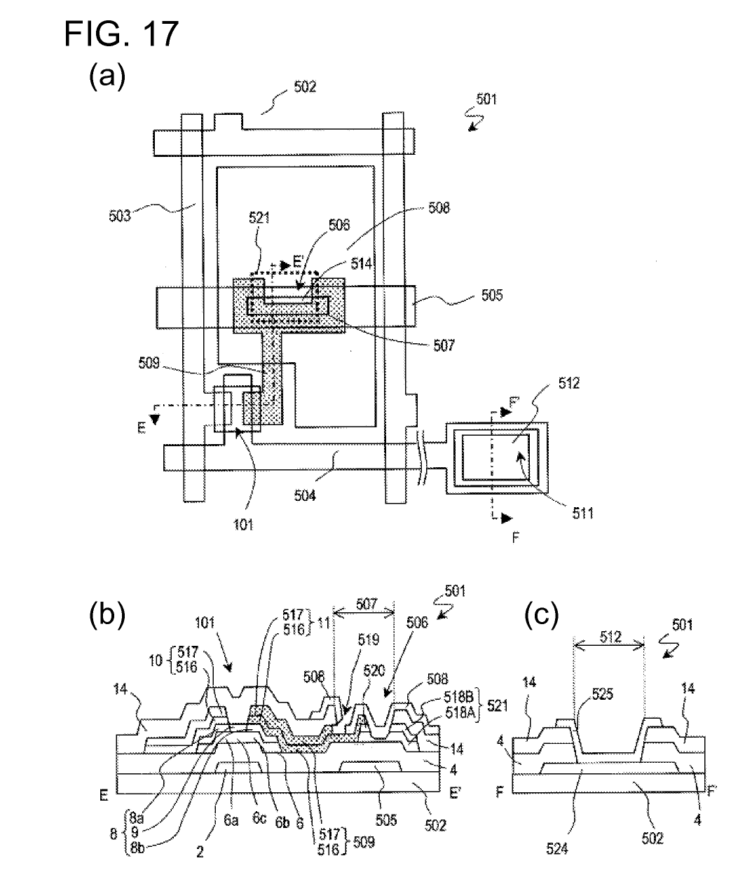

FIG. 17(a) to FIG. 17(c) schematically show an active matrix substrate 501 according to the present embodiment. FIG. 17(a) is a plan view schematically showing a single pixel region in the display region of the active matrix substrate 501 and a single terminal portion region in the peripheral region. FIG. 17(b) and FIG. 17(c) are cross-sectional views taken along the line E-E′ and the line F-F′ of FIG. 17(a), respectively. For convenience, components similar to those in FIG. 1(a) to FIG. 1(c) are given the same reference characters, and their description is omitted.

The active matrix substrate 501 of the present embodiment is equipped with a substrate 502, a plurality of source wires 503 formed on the substrate 502, and a plurality of gate wires 504 and auxiliary capacitance lines 505 extending in a direction perpendicular to the source wires 503. Here, in each region (referred to as a “pixel region”) surrounded by two adjacent source wires 503 and two adjacent gate wires 504, a thin film transistor 101, a connection wire 509 that includes a drain electrode 11 of the thin film transistor 101, a pixel electrode 508, and a contact portion 506 that electrically connects the pixel electrode 508 to the connection wire 509 are provided.

A source electrode 10 of the thin film transistor 101 is connected to the source wire 503. A gate electrode 2 is connected to the gate wire 504. The gate wire 504 extends up to a terminal portion 511 as a gate wire extended portion 524, and is connected to a terminal upper layer electrode 525 inside a contact hole 512 provided in the terminal portion 511.

The connection wire 509 formed of the same layer as the drain electrode 11 of the thin film transistor 101 extends over the auxiliary capacitance line 505 in the pixel region, and overlaps a portion of the auxiliary capacitance line 505. This way, the connection wire 509 forms an auxiliary capacitance (electrical capacitance) with the auxiliary capacitance line 505, and has a function to secure a potential of the pixel electrode 508.

In the portion where the connection wire 509 and the auxiliary capacitance line 505 overlap with each other, an etching protection layer 521 is formed between the connection wire 509 and a gate insulating layer 4. Further, a notch portion 514 is formed in the connection wire 509 such that a portion of the etching protection layer 521 is exposed from the connection wire 509. In a passivation layer 14 and the etching protection layer 521, a contact hole 507 is formed so as to cross the notch portion 514 of the connection wire 509. The pixel electrode 508 is formed on the passivation layer 14 and on an inner wall of the contact hole 507, and is in contact with the connection wire 509, which constitutes a portion of the inner wall of the contact hole 507. In this specification, the portion where the pixel electrode 508 and the connection wire 509 are in contact with each other inside the contact hole 507 is referred to as the “contact portion 506.”

In the present embodiment, the contact hole 507 runs through the passivation layer 14, and reaches the etching protection layer 521 located below. Therefore, the inner wall of the contact hole 507 is constituted of the connection wire 509 and the etching protection layer 521 in addition to the passivation layer 14. According to such a structure, which will be described in detail later, over-etching of the gate insulating layer 4 of the contact hole 507 can be prevented, and the contact hole 507 having an excellent forward tapered shape can be formed.

The etching protection layer 521 has a two-layer structure having a lower layer 518A formed of a microcrystalline silicon film and an upper layer 518B that is formed on the lower layer 518A and that contains a film (oxidized silicon film) obtained by oxidizing a microcrystalline silicon film. In the present embodiment, the lower layer 518A of the etching protection layer 521 and a semiconductor layer 6 of the thin film transistor 101 are formed by patterning the same microcrystalline silicon film (thickness: 20 nm to 60 nm, for example). The upper layer 518B of the etching protection layer 521 and a separation region 9 of a contact formation layer 8 are formed by oxidizing the same n⁺ type microcrystalline silicon film (thickness: 3 nm to 30 nm, for example). A portion 520 of the upper layer 518B that is covered by the connection wire 509 is not oxidized, and is formed of an n⁺ type microcrystalline silicon film. Therefore, according to the present embodiment, the etching protection layer 521 is formed without increasing the number of manufacturing steps.

The etching protection layer 521 functions as a protection layer to protect the gate insulating layer 4 when the contact hole 507 is being formed. Because of this, inside the contact hole 507, a portion or the entirety of the etching protection layer 521 is etched, but the gate insulating layer 4 is not etched. Thus, defects such as leakage and the like due to the gate insulating layer 4 becoming a thinner film can be suppressed. In this specification, in order to facilitate explanation, the etching protection layer 521, the lower layer 518A, and the upper layer 518B are described using the same reference characters before and after the contact hole 507 has been formed.

As shown in FIG. 17(b), the source wire 503, the source electrode 10, the drain electrode 11, and the connection wire 509 of the thin film transistor 101 all have a two-layer structure having a first conductive layer 516 as the lower layer and a second conductive layer 517 as the upper layer. Here, the first conductive layer 516 is a titanium (Ti) layer, and the second conductive layer 517 is an aluminum (Al) layer. However, in the proximity of the contact hole 507, the connection wire 509 is formed only of the first conductive layer 516. Thus, in the contact portion 506, the first conductive layer 516 of the connection wire 509 and the pixel electrode 508 are connected to each other inside the contact hole 507. According to such a structure, the connection wire 509 and the pixel electrode 508 can be electrically connected to each other excellently. This is because the pixel electrode 508 is formed of an ITO (indium tin oxide), for example, and even though it cannot be electrically connected excellently to aluminum, which is the material of the second conductive layer 517, it can be electrically connected excellently to titanium, which is the material of the first conductive layer 516. Instead of titanium, molybdenum may be used as the material for the first conductive layer 516. Also, instead of aluminum, copper may be used as the material for the second conductive layer 517.

As shown in FIG. 17(c), in the terminal portion 511, the contact hole 512, which reaches the gate wire extended portion 524, is provided in the passivation layer 14 and the gate insulating layer 4. The terminal upper layer electrode 525 is provided on the inner wall of the contact hole 512. Because of this, the terminal upper layer electrode 525 and the gate wire extended portion 524 are electrically connected to each other. Thus, signals can be supplied to the gate wire 504 from outside through the terminal portion 511. The terminal upper layer electrode 525 is made of the same material as the pixel electrode 508, for example. Here, it is made of an ITO (indium tin oxide).

In the present embodiment, when forming the contact hole 507 in the passivation layer 14, another contact hole (contact hole 512, for example) can be formed in the passivation layer 14 and the gate insulating layer 4 at the same time in another region of the substrate 501 (terminal portion 511, for example) because the etching protection layer 521 is provided. In such a case, the surface of the substrate is exposed to etching atmosphere even after etching of the passivation layer 14 is completed until formation of the contact hole 512 is completed. Here, in a region where the contact hole 507 is to be formed, the double-layered etching protection layer 521 plays a role to protect the gate insulating layer 4 on the substrate side, and etching damage to the gate insulating layer 4 can be reduced.

As described, etching of the gate insulating layer 4 can be prevented because the etching protection layer 521 according to the present embodiment has the upper layer 518B, which is made of an oxidized silicon film that is highly resistant to dry etching.

Thus, according to the present embodiment, the contact hole 507 and another contact hole can be formed in a single photolithography step using the same resist pattern film while suppressing defects such as a leakage due to the gate insulating layer 4 becoming a thinner film.

When the contact hole 507 is formed, on a wall surface of the contact hole 507 containing an end surface portion of the connection wire 509 (second conductive layer 517), a forward tapered shape is not formed due to an etching side shift or the like. Because of this, a step separation of the pixel electrode 508 may occur on a portion of the wall surface of the contact hole 507 where the forward tapered shape is not obtained (step separation portion 519). Such a portion does not become a path to connect the connection wire 509 to the pixel electrode 508.

In the present embodiment, particularly notable effects can be obtained when wires such as the connection wires 509 and the like have a two-layer structure, such as having an aluminum layer on the upper layer side, and the like. When the connection wire 509 has a two-layer structure, the second conductive layer 517 of the connection wire 509 needs to be removed in the proximity of the contact portion 506. In such a case, when forming a contact hole, the end surface of the second conductive layer 517 tends to be etched. As a result, the contact hole 507 having a forward tapered shape becomes difficult to form, and a step separation of the pixel electrode 508 tends to occur, which is the reason for removing the second conductive layer 517. If a wire having a three-layer structure such as Ti/Al/Ti or the like, for example, is formed, there is no need to etch only the Al layer in the proximity of the contact portion 506. However, the manufacturing costs increase.

In the present embodiment, the thickness of the semiconductor layer 6 and the thickness of the lower layer 518A of the etching protection layer 521 are substantially equal to each other. The thickness is 20 nm or more and 60 nm or less, and is 30 nm, for example. Furthermore, the thickness of the contact formation layer 8 and the thickness of the upper layer 518B of the etching protection layer 521 are substantially equal to each other. The thickness is 3 nm or more and 30 nm or less, and is 10 nm, for example. The thickness of the etching protection layer 521 as a whole, i.e., the sum of the thickness of the lower layer 518A and the upper layer 518B, preferably is 23 nm or more. Here, the thickness of both of these layers 518A and 518B means the thickness of the portion that was not etched when the contact hole 507 was formed (i.e., thickness before etching).

In the structure shown in FIG. 17, the thin film transistor 101 was formed as a pixel switching TFT. The thin film transistor 121 described in Embodiment 2 may be used instead.

The active matrix substrate 501 of the present embodiment is manufactured by the following method, for example.

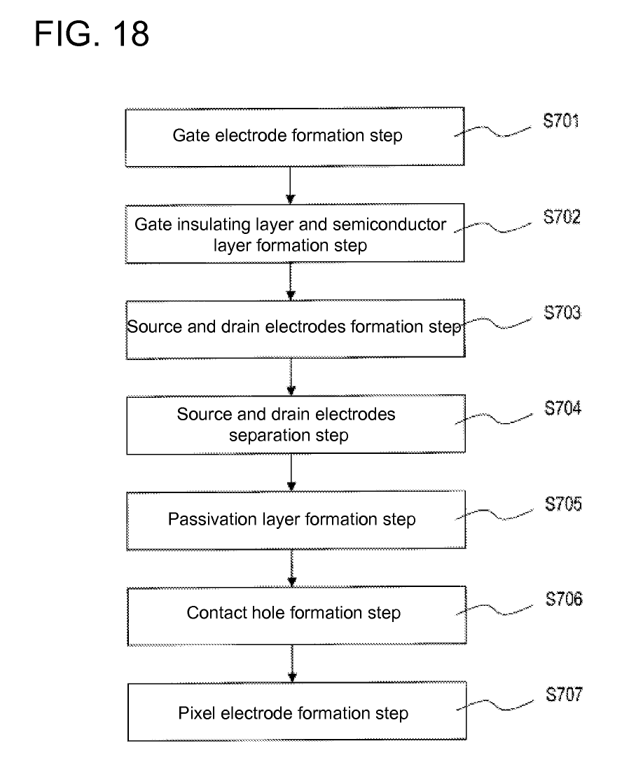

FIG. 18 is a drawing for explaining an overview of a manufacturing method of an active matrix substrate according to the present embodiment. The manufacturing method of the present embodiment includes a gate electrode formation step S701 for forming a gate electrode, a gate insulating layer and semiconductor layer formation step S702 for forming a gate insulating layer and an island-shaped semiconductor layer that becomes an active layer, a source and drain electrodes formation step S703 for forming source and drain electrodes, a source and drain electrodes separation step S704 for electrically disconnecting the source electrode from the drain electrode, a passivation layer formation step S705, a contact hole formation step S706 for forming a contact hole, and a pixel electrode formation step S707. Steps S701 to S705 respectively include the steps S301 to S305 of manufacturing a thin film transistor mentioned above with reference to FIG. 2 and FIGS. 7 to 10. Thus, description regarding the steps S701 to S705 of manufacturing a thin film transistor is omitted below.

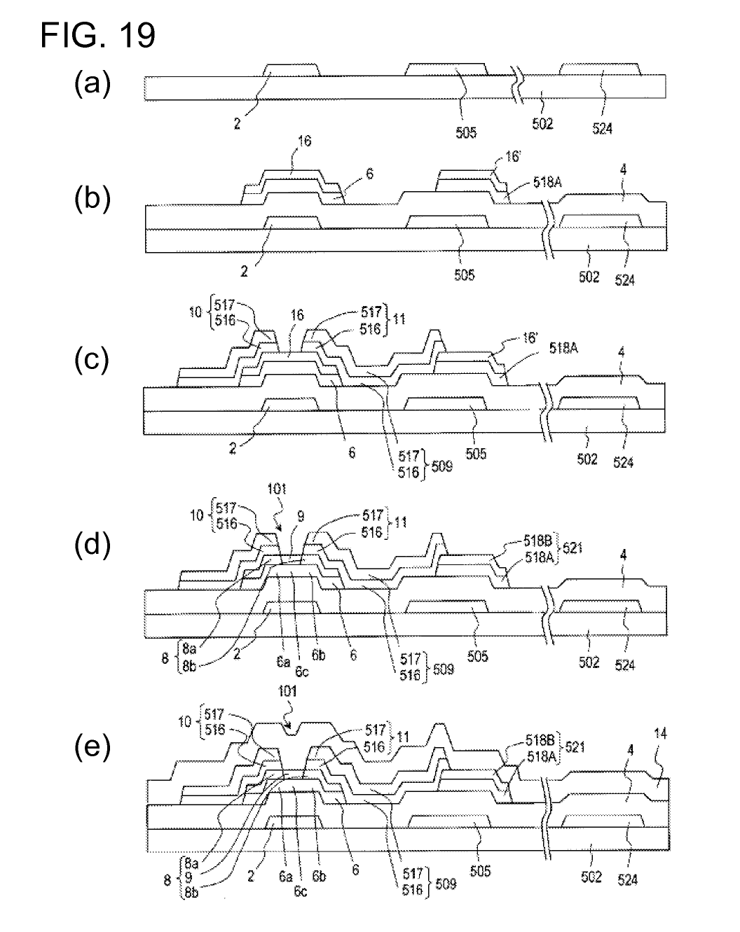

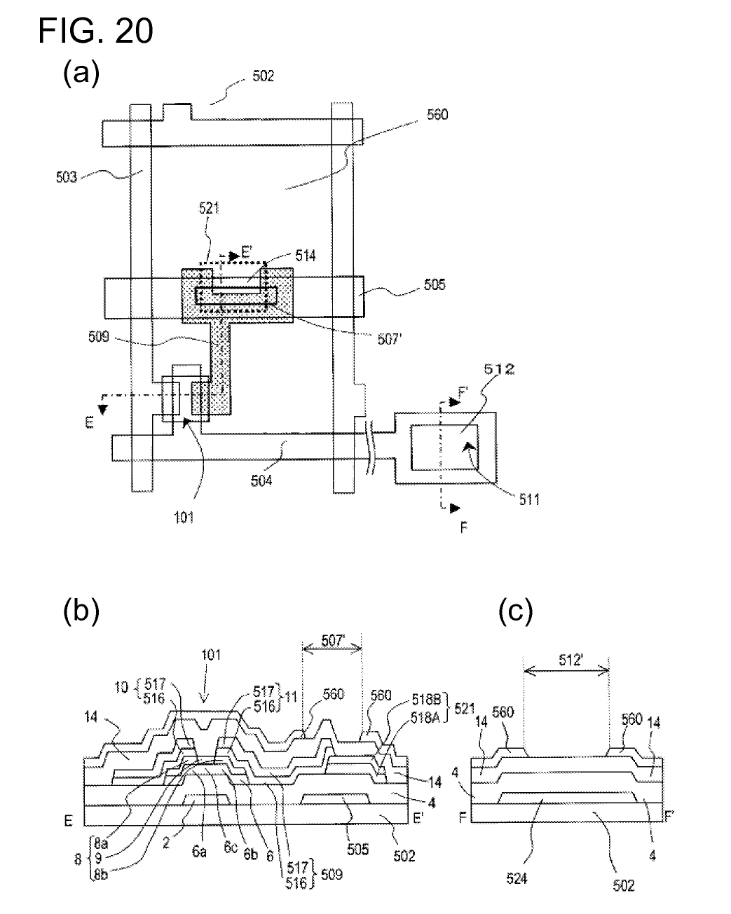

FIG. 19(a) to FIG. 19(e) are schematic cross-sectional views showing process steps for explaining a manufacturing method according to the present embodiment in more detail. FIG. 20(a) to FIG. 20(c) are schematic drawings for explaining a contact hole formation step in the manufacturing method of the present embodiment. FIG. 20(a) is a top view. FIG. 20(b) and FIG. 20(c) are cross-sectional views taken along the line E-E′ and the line F-F′, respectively.

First, as shown in FIG. 19(a), a conductive film is formed on the substrate 502, and is patterned to form the gate electrode 2 and wires, such as, the auxiliary capacitance line 505, the gate wire extended portion 524, and the like (step 701).

Next, as shown in FIG. 19(b), the gate insulating layer 4 is formed to cover the gate electrode 2 and wires, such as, the auxiliary capacitance line 505, the gate wire extended portion 524, and the like. Then, on the gate insulating layer 4, a microcrystalline silicon film and an n⁺ type microcrystalline silicon film are formed and patterned. This way, the semiconductor layer 6 and the lower layer 518A of the etching protection layer are formed of the microcrystalline silicon film, and an n⁺ type microcrystalline silicon layer 16 that becomes a contact formation layer and an n⁺ type microcrystalline silicon layer 16′ that becomes the upper layer of the etching protection layer are formed of the n⁺ type microcrystalline silicon film (step S702).

Then, as shown in FIG. 19(c), a conductive film is formed on the n⁺ type microcrystalline silicon layer 16 and the n⁺ type microcrystalline silicon layer 16′, and is patterned to form the source electrode 10, the drain electrode 11, and the connection wire 509. The source electrode 10 and the drain electrode 11 are formed such that they are located over regions of the semiconductor layer 6 that become the source region and the drain region, respectively. As a result, the surface of the portion of the n⁺ type microcrystalline silicon layer 16 located over the region that becomes the channel region is exposed. The connection wire 509 has a pattern in which a notch portion is provided, and as a result, a surface of a portion of the n⁺ type microcrystalline silicon layer 16′ is exposed (step S703). As the aforementioned conductive film, a conductive film having a multi-layer structure may be formed by forming a Ti film and an Al film in this order.

Next, as shown in FIG. 19(d), only the exposed portions of the n⁺ type microcrystalline silicon layers 16 and 16′ are oxidized. This way, the separation region 9 formed of an oxidized silicon layer is formed in the n⁺ type microcrystalline silicon layer 16, and portions of the n⁺ type microcrystalline silicon layer 16 that were not oxidized become the contact regions 8a and 8b. Meanwhile, a portion of the n⁺ type microcrystalline silicon layer 16′ that is not covered by the connection wire 509 is oxidized, and the portion 520 covered by the connection wire 509 is left as n⁺ type microcrystalline silicon. As a result, a layer 518B that includes an oxidized silicon film is formed. The layer 518B is not entirely formed of an oxidized silicon film, and contains the portion 520 formed of n⁺ type microcrystalline silicon. This way, the etching protection layer 521 formed of the lower layer 518A and the layer (upper layer) 518B is obtained (step S704).

Then, as shown in FIG. 19(e), the passivation layer 14 is formed (step S705), and the active matrix substrate 501 is obtained.

Then, as shown in FIG. 20(a) to FIG. 20(c), a resist pattern film 560 is formed on the passivation layer 14. The resist pattern film 560 has an opening 507′ and an opening 512′ over regions where contact holes are to be formed. The opening 507′ has a shape that crosses across the notch portion 514 of the connection wire 509. Then, using the resist pattern film 560 as a mask, etching is conducted.

This way, in the opening 512′, the passivation layer 14 and the gate insulating layer 4 are etched, and the contact hole 512 shown in FIG. 17 is formed. On the other hand, in the opening 507′, the passivation layer 14 is etched first. As described above, a portion of the etching protection layer 521 is located below the notch portion 514 of the connection wire 509. Because of this, when the passivation layer 14 is etched, not only the connection wire 509, which is below the passivation layer 14, but also the etching protection layer 521 are exposed. The exposed etching protection layer 521 is exposed to etching atmosphere until etching of the gate insulating layer 4 is completed in the opening 512′. Here, the etching protection layer 521 can suppress etching of the gate insulating layer 4 in the opening 507′ because it has the upper layer 518B, which is formed of an oxidized silicon film that is highly resistant to dry etching. Thus, defects such as a leakage and the like due to the gate insulating layer 4 becoming a thinner film can be suppressed.

Then, the Al film is etched so that a portion of the connection wire 509 that is located in the proximity of the region where the contact portion 506 (FIG. 17) is to be formed is formed only of the Ti film. Here, a wet etching method is used, and an aqueous solution containing a phosphoric acid, a nitric acid, and an acetic acid, is used as an etchant. The resist pattern film 560 is removed at an appropriate stage. In addition, although not shown in the figure, on the passivation layer 14 and on the inner wall of the contact hole 507, the pixel electrode 508 is formed. On the passivation layer 14 and on the inner wall of the contact hole 512, the terminal upper layer electrode 525 is formed. The active matrix substrate 501 is obtained this way.

Here, the aforementioned effects according to the present embodiment are described in detail in comparison with a structure of a conventional active matrix substrate.

Patent Document 4 proposes that in an active matrix substrate equipped with an amorphous silicon TFT, an etching protection layer be provided on a gate insulating layer in order to protect the gate insulating layer when forming a contact hole. With such a structure, a drain electrode can be electrically connected to a pixel electrode securely even when a two-layered wire (Al/Ti wire) formed by depositing titanium and aluminum in that order is used for a source wire, a source electrode, the drain electrode, a connection wire, and the like. When this structure is not used, a three-layered wire (Ti/Al/Ti wire or the like) formed of titanium and aluminum needs to be used for the source wire, the source electrode, the drain electrode, the connection wire, and the like.

The active matrix substrate disclosed in Patent Document 4 is equipped with an amorphous silicon TFT having a channel etching structure formed by channel etching. An etching protection layer 521 of Patent Document 4 is formed by patterning the same amorphous silicon film as an active layer of the amorphous silicon TFT, and is an amorphous silicon layer having the thickness that is equal to the thickness of a channel region after channel etching. According to such a structure, etching of the gate insulating layer can be prevented when forming a contact hole. Furthermore, since a contact hole having a forward tapered shape can be formed, step separation of the pixel electrode inside the contact hole can be prevented, and the drain electrode and the pixel electrode can be electrically connected to each other more securely.

However, in the active matrix substrate disclosed in Patent Document 4, when trying to form a microcrystalline silicon TFT having a channel etching structure instead of an amorphous silicon TFT, the structure of Patent Document 4 does not work well as it is. From a standpoint of TFT characteristics, the thickness of the channel region needs to be limited to 100 nm or less, for example, in order to reduce OFF currents. In such a case, the thickness of the etching protection layer also becomes 100 nm or less, and etching of the gate insulating layer may not be prevented sufficiently.

When trying to apply the structure of Patent Document 4 to a microcrystalline silicon TFT as it is, the ratio of etching rate of the microcrystalline silicon film and a silicon nitride film that forms the gate insulating layer is approximately 1:3 to 1:5. Here, when the thickness of the gate insulating layer is set at approximately a typical thickness that is used often (400 nm, for example), the thickness of the etching protection layer needs to be at least 80 nm (when the etching rate ratio is 1:5) or 133 nm or more (etching rate ratio: 1:3). If it is thinner than this, a portion of the gate insulating layer is etched, and the gate insulating film cannot be sufficiently protected. Trying to make the etching protection layer thicker than the channel region by adding a new step increases the number of manufacturing steps, which is not preferable from a standpoint of productivity.

Therefore, characteristics of the microcrystalline silicon TFT and the protective function of the etching protection layer cannot both be adequetly achieved. Or, the range of the thickness of the channel region for combining the TFT characteristics and the protective function becomes extremely narrow. In reality, taking into account an etching distribution in a substrate plane by dry etching and the like, a margin needs to be provided, making the range of the thickness of the channel region even narrower. As a result, a source wire 503, a connection wire 509, and the like need to be changed to a Ti/Al/Ti wire formed of three layers, or the like, for example. This limits selection of materials for the drain electrode, and becomes a cause of a manufacturing cost increase.

In contrast, according to the active matrix substrate 501 of the present embodiment, even when the thickness of the channel region 6c is limited to 30 nm, for example, in order to reduce OFF currents, etching of the gate insulating layer inside the contact hole 507 can be sufficiently prevented. The reason for this is as follows. The thickness of the lower layer 518A of the etching protection layer 521 is the same as the thickness of the channel region 6c (30 nm, for example), but the thickness of the etching protection layer 521 as a whole (sum of the thickness of the lower layer 518A and the upper layer 518B) is thicker than the channel region 6c, and the upper layer 518B of the etching protection layer 521 is formed of oxidized silicon, which is more resistant to dry etching than microcrystalline silicon.

Therefore, characteristics of the microcrystalline silicon TFT and the protective function of the etching protection layer can both be adequetly achieved. Thus, even when the microcrystalline silicon TFT is used, selection of materials for the drain electrode is not limited, which does not cause the manufacturing costs to increase.

As described, according to the present embodiment, the high performance active matrix substrate 501 using a microcrystalline TFT can be manufactured without increasing the manufacturing costs.

### Comparison Example 2

An active matrix substrate according to the comparison example 2 is an active matrix substrate disclosed in Patent Document 4, but is configured to have a microcrystalline silicon TFT instead of an amorphous silicon TFT.

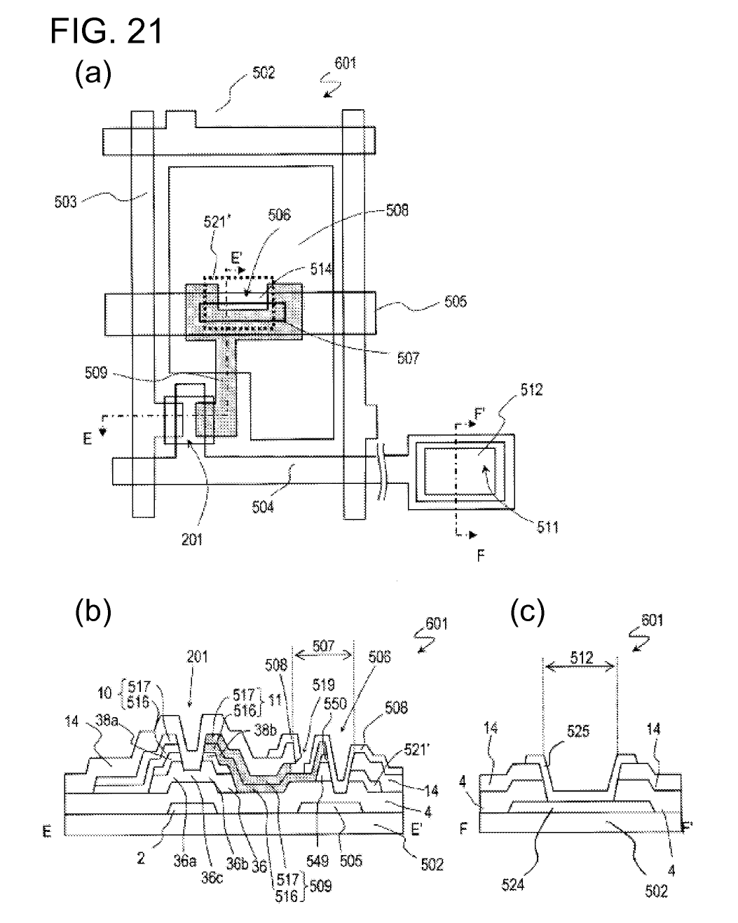

FIG. 21(a) is a top view of the active matrix substrate of the comparison example 2. FIG. 21(b) and FIG. 21(c) are cross-sectional views taken along the line E-E′ and the line F-F′ shown in FIG. 21(a), respectively. An active matrix substrate 601 according to the comparison example 2 has a microcrystalline silicon thin film transistor 201 having an inverted staggered channel etching structure. The structure of the thin film transistor 201 is similar to the structure shown in FIG. 3. For convenience, components similar to those in FIGS. 17 and 3 are given the same reference characters, and their description is omitted.

An etching protection layer 521′ of the active matrix substrate 601 is a microcrystalline silicon layer formed of the same microcrystalline silicon film as a semiconductor layer 36. The thickness of a source region 36a and a drain region 36b of the semiconductor layer 36 is 100 nm, for example, and the thickness of a channel region 36c is 40 nm, for example. This value is set to a range (20 nm to 60 nm) in which excellent TFT characteristics can be obtained. The thickness of a portion of the etching protection layer 521′ that is not covered by a connection wire 509 is substantially equal to the thickness of the channel region 36c, and is 40 nm, for example. The thickness of a portion 549 that is covered by the connection wire 509 is substantially equal to the thickness of the source region 36a and the drain region 36b, and is 100 nm, for example, because it was protected by the connection wire 509 during a channel etching step. Here, the thickness of the etching protection layer 521′ indicates the thickness of a portion that was not etched when a contact hole 507 was being formed.

As shown in FIG. 21(b), in the comparison example 2, the contact hole 507 runs through the etching protection layer 521′ and reaches a gate insulating layer 4. This is because the thickness of the etching protection layer 521′ is not sufficient.

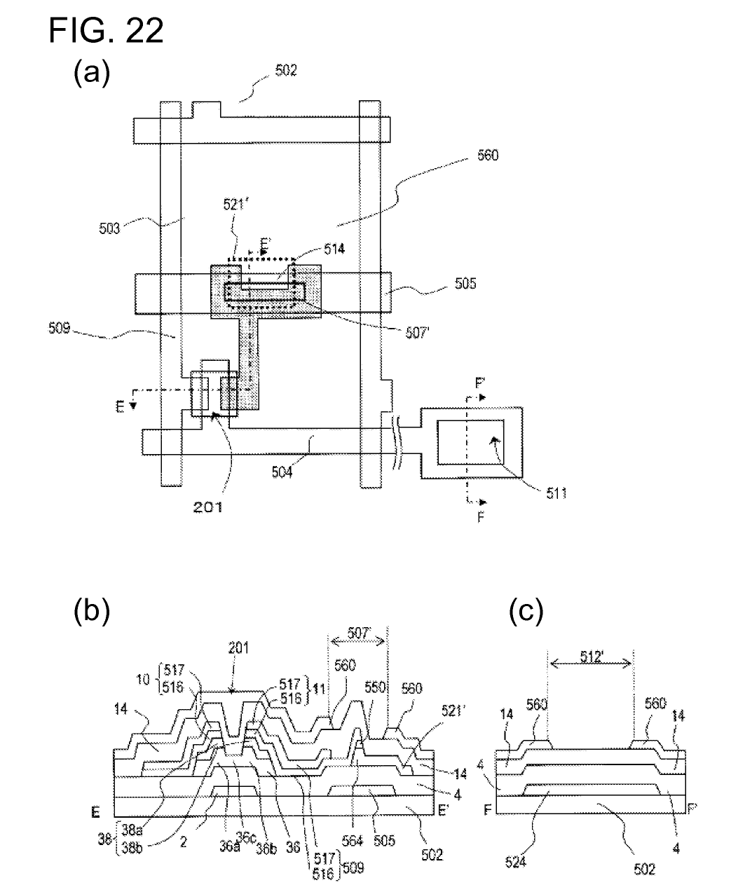

With reference to figures, a contact hole formation step according to a method for manufacturing the active matrix substrate 601 of the comparison example 2 is described. FIG. 22(a) is a top view. FIG. 22(b) and FIG. 22(c) are cross-sectional views taken along the line E-E′ and the line F-F′, respectively. For convenience, components similar to those shown in FIGS. 21 and 20 are given the same reference characters, and their description is omitted.

As shown in FIG. 22(a) to FIG. 22(c), a portion of the etching protection layer 521′ that is covered by a connection wire 506 has a thickness that is substantially equal to the source and drain regions 36a and 36b of the semiconductor layer 36. Over this portion, an n⁺ type microcrystalline silicon layer 550 is formed. On the other hand, a portion of the etching protection layer 521′ that is not covered by the connection wire 506 has a thickness that is substantially equal to the channel region 36c of the semiconductor layer 36. Over this region, the n⁺ type microcrystalline silicon layer 550 is not formed. This is because the n⁺ type microcrystalline silicon layer 550 on the etching protection layer 521′ and a surface portion of the etching protection layer 521′ were etched in a channel etching step.

On such an etching protection layer 521′ and the thin film transistor 201, a passivation layer 14 is formed. Then, on the passivation layer 14, a resist pattern film 560 having an opening 507′ and an opening 512′ over regions where contact holes are to be formed is formed.

Then, etching is performed using the resist pattern film 560 as a mask. This way, in the opening 507′, the passivation layer 14 and the etching protection layer 521′ are etched, thereby forming the contact hole 507 shown in FIG. 21. In the opening 512′, the passivation layer 14 and the gate insulating layer 4 are etched, thereby forming the contact hole 512 shown in FIG. 21.

Here, before etching of the passivation layer (silicon nitride layer, for example) 14 and the gate insulating layer (silicon nitride layer, for example) 4 is completed in the opening 512′, etching of the passivation film 14 and the etching protection layer 521′ is completed in the opening 507′ because the thickness of the etching protection layer 521′ is not sufficient. As a result, the gate insulating layer 4 is etched in the opening 507′. Thus, as described above with reference to FIG. 21(b), the contact hole 507, which runs through the passivation layer 14 and the etching protection layer 521′ and reaches the gate insulating layer 4, is formed.

As described, according to the comparison example 2, the gate insulating layer 4 cannot be sufficiently protected by the etching protection layer 521′. When the gate insulating layer 4 is etched and becomes thin inside the contact hole 507, there may be a risk that defects, such as, an occurrence of a leakage between a pixel electrode 508 and an auxiliary capacitance wire 505, and the like occur. On the other hand, trying to thicken the etching protection layer 521′ in order to secure the protective function of the etching protection layer 521′ thickens the channel region 36c as well, which increases OFF currents of the thin film transistor 201.

Thus, in the comparison example 2, it is very difficult to adequetly achieve the characteristics of the microcrystalline silicon TFT and the protective function of the etching protection layer. Therefore, selection of materials for the drain electrode becomes limited in order to secure the protective function, which causes an increase in the manufacturing costs. Securing the protective function by adding a new step to make the etching protective layer thicker than the channel region can be considered. However, according to this method, the number of manufacturing steps increases, which is not preferable from a standpoint of productivity.

In contrast, according to the active matrix substrate 501 (FIG. 17) of the present embodiment, as described above, OFF characteristics of the microcrystalline silicon thin film transistor 101 and the protective function of the etching protection layer 521 can both be adequetly achieved without limiting materials of the drain electrode.

### INDUSTRIAL APPLICABILITY

The present invention can be widely applied to a circuit board such as an active matrix substrate and the like, a display device such as a liquid crystal display device, an organic electroluminescence (EL) display device, an inorganic electroluminescence display device, and the like, an imaging device such as a flat panel type X-ray image sensor device and the like, and a device equipped with a thin film transistor, such as an electronic device and the like, including an image input device, a finger print reading device, and the like. Particularly, the present invention can be suitably applied to a liquid crystal display device having an excellent display quality by double-speed drive or the like, a low-power consumption liquid crystal display device, a larger liquid crystal display device, or the like.

### DESCRIPTION OF REFERENCE CHARACTERS

1 substrate
2 gate electrode
4 gate insulating layer
6 semiconductor layer (microcrystalline silicon layer)
6a source region
6b drain region
6c channel region
8 contact formation layer
8a, 8b contact regions
9 separation region
10 source electrode
11 drain electrode
14 passivation layer
16 n⁺ type microcrystalline silicon layer
18 resist pattern film
19 oxidized silicon layer
20 amorphous silicon layer
101, 111, 121 thin film transistors
400, 420, 501, 601 active matrix substrates
502 substrate
503 source wire
504 gate wire
505 auxiliary capacitance line
506 contact portion
507 contact hole
508 pixel electrode
509 connection wire
511 terminal portion
512 contact hole of terminal portion
514 notch portion of connection wire
518A lower layer of etching protection layer
518B upper layer of etching protection layer
520 n⁺ type microcrystalline silicon portion
521 etching protection layer
524 gate wire extended portion
525 terminal upper layer electrode

1. A semiconductor device, comprising:
a substrate;
an active layer formed on said substrate having a channel region, a first region located on one side of said channel region, and a second region located on the other side of said channel region;
a contact formation layer formed on said active layer, having a first contact region located on said first region of said active layer, a second contact region located on said second region of said active layer, and a separation region located between said first contact region and said second contact region;
a first electrode electrically connected to said first region through said first contact region;
a second electrode electrically connected to said second region through said second contact region; and
a gate electrode provided with respect to said active layer through a gate insulating layer,
wherein said active layer and said first and second contact regions are made of microcrystalline silicon films, and
wherein said separation region is made of an oxidized microcrystalline silicon film.

2. The semiconductor device according to claim 1, further comprising an amorphous silicon layer between the channel region of said active layer and the separation region of said contact formation layer.

3. The semiconductor device according to claim 1, wherein a volume fraction of a crystalline phase in the microcrystalline silicon film of said first and second contact regions is higher than a volume fraction of a crystalline phase in the microcrystalline silicon film of said active layer.

4. The semiconductor device according to claim 3, wherein an average grain size of microcrystal grains in the microcrystalline silicon film of said first and second contact regions is larger than an average grain size of microcrystal grains in the microcrystalline silicon film of said active layer.

5. The semiconductor device according to claim 1, further comprising:
a protective layer formed between said gate insulating layer and a second electrode wire that includes said second electrode in a region of said substrate that is different from a region where said active layer is formed;
an interlayer insulating layer formed on said first electrode, said second electrode wire, and said protective layer, wherein a contact hole that runs through said interlayer insulating layer to reach said protective layer is formed in said interlayer insulating layer and in said protective layer; and
a conductive film formed over said interlayer insulating layer and inside said contact hole,
wherein said conductive film is electrically connected to said second electrode wire inside said contact hole, and
wherein said protective layer comprises:
a lower layer made of a microcrystalline silicon film; and
an upper layer that is formed over said lower layer and that includes an oxidized microcrystalline silicon film.

6. The semiconductor device according to claim 1, wherein a thickness of said active layer is 20 nm or more and 60 nm or less.

7. The semiconductor device according to claim 1, wherein a thickness of said first and second contact regions is 3 nm or more and 30 nm or less.

8. The semiconductor device according to claim 1, wherein said active layer comprises a plurality of microcrystal grains and crystal grain boundaries located between adjacent microcrystal grains, and
wherein each microcrystal grain extends to form a column-shape in a direction parallel to a direction normal to said substrate.

9. A method for manufacturing a semiconductor device, comprising:
(A) forming a gate electrode on a substrate;
(B) forming a gate insulating layer so as to cover said gate electrode;
(C) forming a first microcrystalline silicon layer that becomes an active layer on said gate insulating layer;
(D) forming a second microcrystalline silicon layer on said first microcrystalline silicon layer; and
(E) oxidizing a portion of said second microcrystalline silicon layer located on a portion that becomes a channel region of said first microcrystalline silicon layer to form a separation region that divides a region of said second microcrystalline silicon layer that was not oxidized into two regions that are electrically disconnected, a first region of said two regions being a first contact region and a second region of said two regions being a second contact region.

10. The method for manufacturing a semiconductor device according to claim 9, further comprising:
forming an amorphous silicon layer on said first microcrystalline silicon layer between said step (C) and said step (D),
wherein said second microcrystalline silicon layer is oxidized using said amorphous silicon layer as an oxidization stop layer in said step (E).

11. The method for manufacturing a semiconductor device according to claim 9, wherein said step (D) includes forming the second microcrystalline silicon layer having a higher volume fraction of a crystalline phase than said first microcrystalline silicon layer.

12. The method for manufacturing a semiconductor device according to claim 9, further comprising:
(C′) forming a third microcrystalline silicon layer over said gate insulating layer in a region that is different from a region where said first microcrystalline silicon layer is formed, which is conducted at the same time as said step (C);
(D′) forming a fourth microcrystalline silicon layer over said third microcrystalline silicon layer, which is conducted at the same time as said step (D);
(F) forming a first electrode that is in contact with a region of said second microcrystalline silicon layer that becomes the first contact region and forming a second electrode wire including a second electrode that is in contact with a region of said second microcrystalline silicon layer that becomes the second contact region, which is conducted between said step (D) and said step (E), wherein said second electrode wire covers only a portion of said fourth microcrystalline silicon layer;
(E′) oxidizing a portion of said fourth microcrystalline silicon layer that is not covered by said second electrode wire to form a layer including an oxidized silicon film, thereby forming a protective layer made of a layer including said third microcrystalline silicon layer and said oxidized silicon film, which is conducted at the same time as said step (E);
(G) forming an interlayer insulating layer that covers said first electrode, the second electrode wire, and said protective layer, which is conducted after said step (E);
(H) forming a contact hole that exposes a portion of said second electrode wire in said interlayer insulating layer and said protective layer; and
(I) forming a conductive film on said interlayer insulating layer and inside said contact hole.
